(19) United States
(12) Patent Application Publication
(10) Pub. No.: US 2026/0040768 A1
(43) Pub. Date: Feb. 5, 2026

(54) LIGHT EMITTING DISPLAY DEVICE

(71) Applicant: LG Display Co., Ltd., Seoul (KR)

(72) Inventors: Yong Cheol KIM, Paju-si (KR); Kyu Il HAN, Paju-si (KR); Mi Na KIM, Paju-si (KR); So Hee LEE, Paju-si (KR)

(73) Assignee: LG Display Co., Ltd., Seoul (KR)

(21) Appl. No.: 19/247,389

(22) Filed: Jun. 24, 2025

(30) Foreign Application Priority Data
Jul. 31, 2024 (KR) 10-2024-0101852

(51) Int. Cl. H10K 59/122; H10K 50/18; H10K 59/00

(52) U.S. Cl. CPC H10K 59/122; H10K 50/181; H10K 59/771

(57) ABSTRACT

A light emitting display device may include a first insulating film having recess portions and a flat portion between adjacent recess portions at first and second subpixels adjacent to each other, a first electrode in a recess portion of each of the first and second subpixels, a dummy pattern on the flat portion of the first insulating film and spaced apart from the first electrode, a first electron blocking layer at the first subpixel and a second electron blocking layer at the second subpixel, the first and second electron blocking layers having an edge on the dummy pattern and spaced apart from each other, a first color light emitting layer provided at the first subpixel and covering the edge of the first electron blocking layer, a second color light emitting layer on the second electron blocking layer, and a second electrode on the first and second color light emitting layers.

### CROSS-REFERENCE TO RELATED APPLICATIONS

This application claims the benefit of and priority to Korean Patent Application No. 10-2024-0101852, filed on Jul. 31, 2024, the entire contents of which are incorporated herein by reference for all purposes as if fully set forth herein.

### BACKGROUND

### 1. Technical Field

The present disclosure relates to a display device, and particularly to, for example, without limitation, a light emitting display device that is capable of expanding a light emitting portion through structural change and simultaneously preventing poor visibility by provision of an off-state charge discharge path.

### 2. Description of Related Art

With the advent of the information society, there is increasing demand for various forms of display devices for displaying images.

A light emitting display device that includes light emitting elements to constitute pixels does not require a separate light source unit and is thus advantageous for slimness or flexibility and has excellent color purity.

For example, a light emitting element includes two different electrodes and a light emitting layer between the electrodes. When electrons generated from one electrode and holes generated from the other electrode are injected into the light emitting layer, the electrons are combined with the holes to form excitons and the energy of the excitons drops from the excited state to the ground state, thus causing light emission.

Light emitting display devices use banks to define a light emitting portion of each subpixel, but have limited resolution because the areas occupied by the banks do not emit light.

The description of related art should not be considered prior art merely because it is mentioned in or associated with this section. The description of related art includes information that describes one or more aspects of the subject technology, and the description in this section does not limit the scope of the invention.

### SUMMARY

Accordingly, one or more aspects of the present disclosure are directed to a light emitting display device that substantially obviates one or more problems due to the limitations and disadvantages of the related art.

One aspect of the present disclosure is to solve limitation of an area of a light emitting portion in a structure in which the light emitting portion is defined by a bank and to expand the area of the light emitting portion.

Another aspect of the present disclosure is to solve a problem of screen dragging in an off state due to charge accumulation that occurs in an electron-blocking layer configured to block electrons between a first electrode and a light emitting layer in the subpixel.

Additional advantages, aspects, and features of the disclosure will be set forth in part in the description which follows and in part will become apparent to those having ordinary skill in the art upon examination of the following, or may be learned from practice of the disclosure. The objectives and other advantages of the disclosure may be realized and attained by the structure particularly pointed out in the written description and claims hereof as well as the appended drawings.

The light emitting display device of the present disclosure may expand a light emitting area by changing an insulating film structure defining a light emitting portion. The light emitting display device of the present disclosure may solve the problem of poor visibility such as screen dragging by providing a dummy pattern to generate a charge discharge path in an off state.

The light emitting display device of the present disclosure may solve the problem of poor visibility such as screen dragging in an off state by providing a dummy pattern on an insulating film structure to define a light emitting portion.

In accordance with one aspect of the present disclosure, provided is a light emitting display device including a first insulating film at first and second subpixels adjacent to each other, the first insulating film having recess portions and a flat portion between adjacent recess portions, a first electrode in a recess portion of each of the first and second subpixels, a dummy pattern on the flat portion of the first insulating film and spaced apart from the first electrode, a first electron blocking layer at the first subpixel and a second electron blocking layer at the second subpixel, the first electron blocking layer and the second electron blocking layer having an edge on the dummy pattern and being spaced apart from each other, a first color light emitting layer at the first subpixel, the first color light emitting layer covering the edge of the first electron blocking layer, a second color light emitting layer on the second electron blocking layer, and a second electrode on the first and second color light emitting layers.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a schematic diagram illustrating a light emitting display device according to one embodiment of the present disclosure.

FIG. 2 is a plan view illustrating a light emitting display device according to one embodiment of the present disclosure.

FIG. 3 is a cross-sectional view taken along the line I-I′ in FIG. 2.

FIGS. 4 and 5 are cross-sectional views illustrating a first embodiment and a second embodiment of the structure of the region A of FIG. 3, respectively.

FIG. 6 is an energy band diagram of a light emitting element within the light emitting portion according to one embodiment.

FIG. 7 is an energy band diagram between the dummy pattern of the region B of FIG. 4 and the second electrode.

FIG. 8 is a cross-sectional view illustrating an example of a stacked structure of region B and the light emitting portion of the first embodiment.

FIG. 9 is an energy band diagram between the dummy pattern of the region C of FIG. 5 and the second electrode.

FIG. 10 is a cross-sectional view illustrating an example of the stacked structure of the region C and the light emitting portion according to the second embodiment.

FIG. 11 is a cross-sectional view illustrating an example of a stacked structure of a light emitting portion and a dummy pattern region of a light emitting display device according to a third embodiment of the present disclosure.

FIG. 12 is a plan view illustrating a light emitting display device according to an embodiment of the present disclosure.

FIG. 13 is a cross-sectional view illustrating a dummy pattern region according to another embodiment of a light emitting display device according to the present disclosure.

FIG. 14 is a graph showing a change in brightness over time in first to third experimental examples when the black screen is driven.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to various embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on,” “above,” “under” and “next to,” at least one intervening element can be present between the two elements, unless “immediate(ly)” or “direct(ly)” or “close(ly)” is used. It will be understood that when an element or layer is referred to as being “connected to,” or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “LUMO (lowest unoccupied molecular orbital) energy level” and “HOMO (highest occupied molecular orbital) energy level” of a layer refer to the LUMO energy level and HOMO energy level of a material that occupies most of a weight ratio of the layer, for example, a host material, unless the context clearly mentions that the LUMO energy level and the HOMO energy level mean the LUMO energy level and HOMO energy level of a dopant material with which the layer is doped, respectively.

Here, the HOMO energy level is obtained by measuring the voltage corresponding to a first peak at which electrons are discharged from a target material through cyclic voltammetry (CV) while comparing with a reference material whose HOMO energy level is known.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, and when the n-type material is present in an amount of less than 30 wt %, or when the p-type material is present in an amount of less than 30 wt %, the layer is considered to be a “doped” layer.

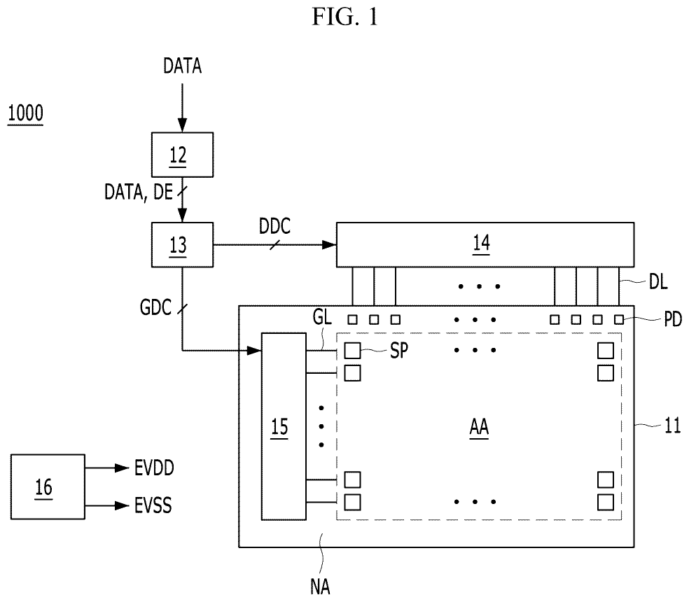

FIG. 1 is a schematic diagram illustrating a light emitting display device according to one embodiment of the present disclosure.

As shown in FIG. 1, the light emitting display device 1000 according to an embodiment of the present disclosure includes a display panel 11, an image processor 12, a timing controller 13, a data driver 14, a scan driver 15, and a power supply 16.

The display panel 11 displays an image in response to a data signal DATA supplied from the data driver 14, a scan signal supplied from the scan driver 15, and power supplied from the power supply 16.

The display panel 11 may include subpixels SP disposed at each intersection of a plurality of gate lines GL and a plurality of data lines DL. The structure of the subpixel SP may vary depending on the type of the light emitting display device 1000.

For example, the subpixels SP may be formed in a top emission method, a bottom emission method, or a dual emission method depending on the structure. The subpixels SP are units that can emit light of their own color with or without a specific type of color filter. For example, the subpixels SP may include a red subpixel, a green subpixel, and a blue subpixel. Alternatively, the subpixel SP may include, for example, a red subpixel, a blue subpixel, a white subpixel, and a green subpixel. The subpixels SP may have one or more different light emitting portions depending on the light emitting characteristics. For example, the blue subpixel and the subpixels emitting light with different color may have different light emitting portions.

One or more subpixels SP may constitute one unit pixel. For example, one unit pixel may include red, green, and blue subpixels, and the red, green, and blue subpixels may be repeatedly disposed. Alternatively, one unit pixel may include red, green, blue, and white subpixels, and the red, green, blue, and white subpixels may be disposed repeatedly, or the red, green, blue, and white subpixels may be disposed in quads. In an embodiment according to the present disclosure, the color type, arrangement type, arrangement order, or the like of the subpixels may be determined depending on the light emission characteristics, lifespan of the device, device specification, etc., and are not limited thereto.

The display panel 11 may be divided into an active area (AA: inside a dotted area) where subpixels SP are disposed to display an image, and a non-active area NA around the active area NA. The scan driver 15 may be mounted in the non-active area NA of the display panel 11. In addition, the non-active area NA may include a pad portion including a pad electrode PD.

Here, the active area AA is also called an “a display region” and the non-active area NA is also called a “non-display region.”

The image processer 12 may output a data enable signal DE in addition to a data signal DATA supplied from the outside. The image processer 12 may output one or more of a vertical synchronization signal, a horizontal synchronization signal, and a clock signal in addition to the data enable signal DE, but these signals are omitted for convenience of description.

The timing controller 13 may receive a data signal DATA in addition to a driving signal from the image processer 12. The driving signal may include a data enable signal DE. In addition, the driving signal may include a vertical synchronization signal, a horizontal synchronization signal, and a clock signal. The timing controller 13 may generate a data timing control signal DDC for controlling the operation timing of the data driver 14 and a gate timing control signal GDC for controlling the operation timing of the scan driver 15 based on the driving signal.

The data driver 14 samples and latches the data signal DATA supplied from the timing controller 13 in response to the data timing control signal DDC supplied from the timing controller 13, converts the resulting the data signal DATA into a gamma reference voltage, and outputs the gamma reference voltage.

The data driver 14 may output the data signal DATA through the data lines DL. The data driver 14 may be provided as an integrated circuit IC. For example, the data driver 14 may be electrically connected to the pad electrode PD disposed in the non-active area NA of the display panel 11 through a flexible circuit film (not shown).

The scan driver 15 may output a scan signal in response to the gate timing control signal GDC supplied from the timing controller 13. The scan driver 15 may output a scan signal through the gate lines GL. The scan driver 15 may be implemented in the form of an integrated circuit IC or may be implemented in the display panel 11 in the form of a gate in panel GIP.

The power supply 16 may output a high potential voltage and a low potential voltage for driving the display panel 11. The power supply 16 may supply a high potential voltage to the display panel 11 through a first power line EVDD (driving power line or pixel power line) and supply a low potential voltage to the display panel 11 through a second power line EVSS (auxiliary power line or a common power line).

The display panel 11 is divided into an active area AA and a non-active area NA, and include a plurality of subpixels SP defined by gate lines GL and data lines DL which cross each other in the active area AA to form a matrix.

The subpixels SP may include emitting subpixels that emit at least two light among red light, green light, blue light, yellow light, magenta light, and cyan light. In addition, the subpixels SP may emit their own color of light with or without a specific type of color filter, but the present disclosure is not necessarily limited thereto. The color type, arrangement type, and arrangement order of the subpixels SP may be determined depending on light emission characteristics, lifespan of the device, and device specification.

Each of the subpixels SP may include a light emitting portion that emits light and a non-light emitting portion around the light emitting portion.

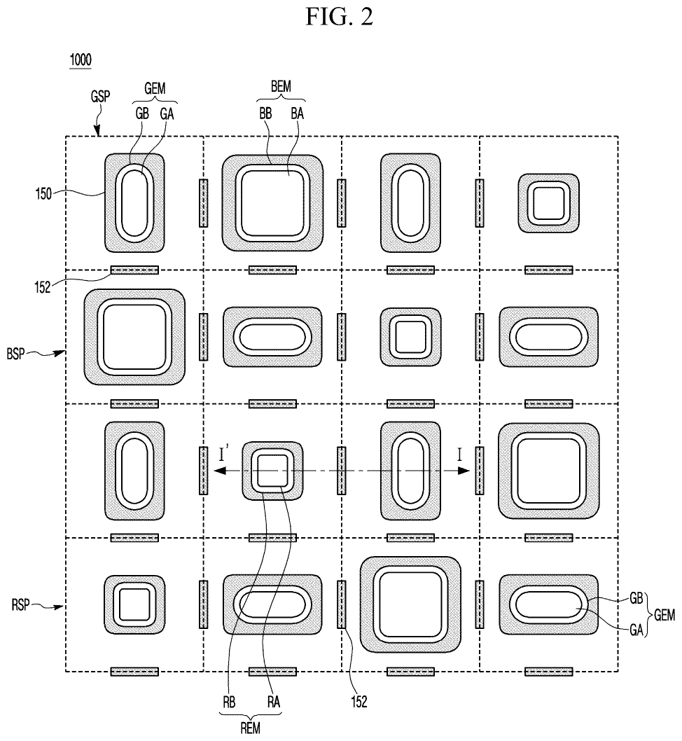

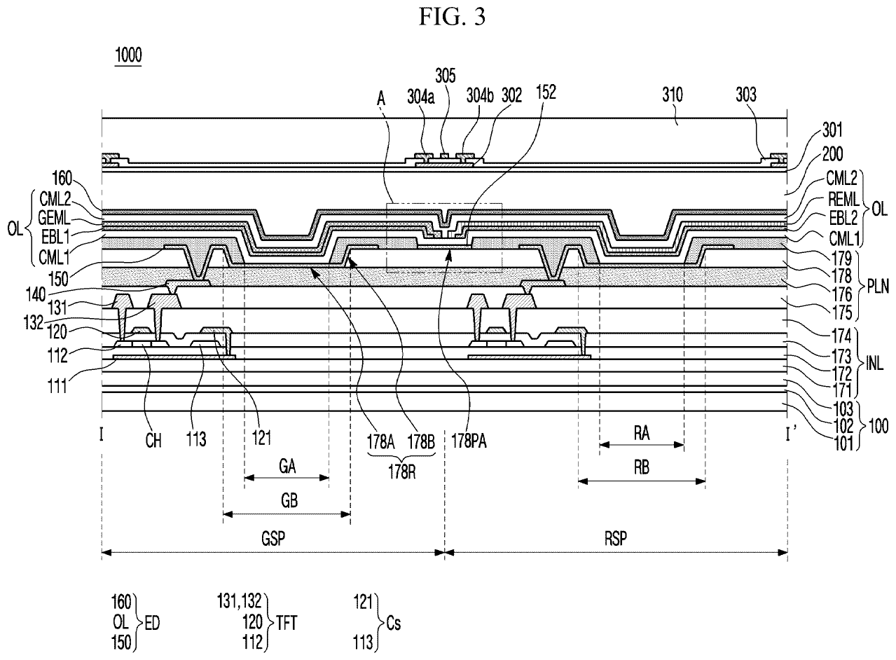

FIG. 2 is a plan view illustrating a light emitting display device according to one embodiment of the present disclosure and FIG. 3 is a cross-sectional view taken along the line I-I′ in FIG. 2.

As shown in FIGS. 2 and 3, the light emitting display device according to one embodiment of the present disclosure includes a first insulating film 178 at first subpixel GSP and second subpixels RSP, a first electrode 150, a dummy pattern 152 spaced apart from the first electrode 150 over the first insulating film 178, a first electron-blocking layer EBL1 at the first subpixels GSP, a second electron-blocking layer EBL2 at the second subpixel RSP, a first color light emitting layer GEML at the first subpixel, a second color light emitting layer REML on the second electron blocking layer EBL2, and a second electrode 160 on the first and second color light emitting layers GEML and REML. The second color light emitting layer REML may emit light with a longer wavelength than the first color light emitting layer GEML.

The first insulating film 178 has recces portions 178R and flat portions 178PA. The recess portion 178R of the first insulation film 178 is provided at each of first subpixels GSP and second subpixels RSP. The flat portion 178PA of the first insulation film 178 is provided between adjacent recess portions 178R.

The first electrode 150 is provided in the recess portion 178R of each of the first and second subpixels GSP and RSP.

The dummy pattern 152 is disposed on the flat portion 178PA of the first insulating film.

Each of the first electron-blocking layer EBL1 and a second electron-blocking layer EBL2 have an edge on the dummy pattern 152. The first electron-blocking layer EBL1 and a second electron-blocking layer EBL2 may be spaced apart from each other on the dummy pattern 152. The first electron-blocking layer EBL1 and a second electron-blocking layer EBL2 may be provided respectively at the first and second subpixels GSP and RSP.

The first color light emitting layer GEML may cover the edge of the first electron-blocking layer EBL1.

The light emitting element ED that emits a predetermined light at each subpixel GSP, RSP, and BSP includes the first electrode 150, an intermediate layer OL, and the second electrode 160. The first electrode 150 is provided in each of the subpixels GSP, RSP and BSP, and is spaced apart from another first electrode 150 in the adjacent subpixel, as shown in FIGS. 2 and 3.

The first subpixel GSP may emit green light, the second subpixel RSP may emit red light, and the third subpixel BSP may emit blue light. The embodiment of FIG. 2 illustrates an example in which a dummy pattern 152 is provided around the first subpixel GSP that emits green light, but dummy patterns may also be provided around other subpixels RSP and BSP. In addition, although the embodiment of FIG. 2 illustrates an example in which a green subpixel, a red subpixel, and a blue subpixel are disposed as the first to third subpixels, the light emitting display device of the present disclosure is not limited to this embodiment. In addition, the light emitting display device according to one embodiment of the present disclosure may further include subpixels that emit light of other color in addition to the green, red, and blue subpixels. For example, the light emitting display device according to one embodiment of the present disclosure may further include white subpixels. Alternatively, the light emitting display device according to another embodiment of the present disclosure may include a combination of color subpixels, which is different from a combination of green, red, and blue subpixels.

Green light emission means, for example, light emission having a peak at a wavelength of 500 nm to 590 nm, red light emission means light emission having a peak at a wavelength of 600 nm to 650 nm, and blue light emission means light emission having a peak at a wavelength of 410 nm to 490 nm.

The light emitting portion GEM, REM and BEM of each subpixel GSP, RSP, and BSP may be a region including a first light emitting portion GA, RA, or BA, and a second light emitting portion GB, RB, or BB.

The light emitting display device according to the embodiment of the present disclosure may increase light emission using side light from the second light emitting portion GB, RB, or BB at each subpixel compared to a structure in which the light emitting portion is defined by the area of the pixel-defining film, thereby improving luminous efficacy.

The first electrode 150 may be independently provided at each subpixel GSP, RSP, or BSP. In order to independently drive the light emitting element of each subpixel GSP, RSP, or BSP, the first electrodes 150 of adjacent subpixels may be spaced apart from each other. A dummy pattern 152 formed of the same material as the first electrode 150 is provided on the flat portion 178PA of the first insulating film 178. The dummy pattern 152 may be spaced apart from each of the first electrodes 150 of the adjacent first and second subpixels GSP and RSP.

The first electrode 150 may include a reflective electrode. The first electrode 150 is provided for each subpixel and is also called a “pixel electrode.” The first electrode 150, a second electrode 160 facing the first electrode 150, and an intermediate layer disposed between the first and second electrodes 150 and 160 constitute the light emitting element ED. One of the first electrode 150 and the second electrode 160 may be an anode and the other may be a cathode.

The first electrode 150 may be provided with a multilayered structure of a reflective electrode and a transparent electrode. For example, the first electrode 150 may be formed as a stacked structure of a first transparent electrode layer/reflective electrode layer/a second transparent electrode layer, or may include at least one reflective electrode layer and at least one transparent electrode layer. The reflective electrode layer includes a metal or metal alloy having high reflection efficiency. For example, the reflective electrode layer may be formed as a single layer or multiple layers including any one selected from the group consisting of silver (Ag), gold (Au), aluminum (Al), copper (Cu), molybdenum (Mo), palladium (Pd), titanium (Ti), nickel (Ni), chromium (Cr), and tungsten (W), and an alloy thereof. The transparent electrode layer may be formed as at least one of tin oxide (TO), zinc oxide (ZO), indium-tin oxide (ITO), indium-zinc oxide (IZO), and indium-tin-zinc oxide (ITZO). In addition, when the first electrode 150 includes a plurality of reflective electrode layers, the plurality of reflective electrode layers may contain the same metal. Alternatively, the reflective electrode layers may contain a shielding metal or metal alloy in at least one reflective electrode layer in order to block hydrogen or outgas generated in insulating films INL, and PLN provided on the substrate 100. In addition, when the first electrode 150 includes a plurality of transparent electrode layers, the plurality of transparent electrode layers may include the same metal oxide. Alternatively, the transparent electrode layer of multiple layers may include a shielding metal or metal alloy in at least one of the transparent electrode layers in order to block hydrogen or outgas generated in the insulating films INL, and PLN provided on the substrate 100.

The recess portion 178R of the first insulating film 178, which is a formation surface of the first electrode 150, has a flat bottom surface 178A disposed at the bottom and a side surface 178B that gradually widens toward the top. In this case, the internal angle formed by the side surface 178B of the recess portion 178R of the first insulating film 178 and the first insulating film 178 may be 90° or less. Preferably, the internal angle formed by the side surface 178B of the recess portion 178R and the first insulating film 178 may be 15° to 80°. The bottom surface 178A of the recess portion 178R may be provided within the first insulating film 178, or, as shown in FIG. 3, the first insulating film 178 may be removed in the full thickness from the recess portion 178R to correspond to the bottom surface 178A of the recess portion 178R so that the top surface of the second insulating film 176 disposed below the first insulating film 178 may be exposed. The top surface of the first insulating film 178 may be the flat portion 178PA.

In some cases, the first insulating film 178 and the second insulating film 176 may be integrated. When the bottom surface 178A of the recess portion is provided within the first insulating film 178, the second insulating film 176 below the bottom surface 178A of the recess portion 178R may be not exposed and the recess portion 178R may be provided at a predetermined depth from the top surface of the first insulating film 178. In this case, the bottom surface 178A of the recess portion may have a predetermined thickness on the top surface of the second insulating film 176, and the predetermined thickness of the bottom surface 178A of the recess portion on the top surface of the second insulating film 176 may be smaller than the thickness of the flat portion 178PA of the first insulating film 178.

The first electrode 150 may be formed, for example, not only on the bottom surface 178A of the recess portion 178R but also on the side surface 178B and may have a shape in which the first electrode 150 disposed on the flat bottom surface 178A extends to the side surface 178B having a predetermined incline with respect to the surface of the substrate 100. The first electrode 150 may be provided along the bottom surface 178A of the recess portion 178R and the side surface 178B surrounding the bottom surface 178A of the recess portion 178R at each of the first subpixel and the second subpixel. As another example, the first electrode 150 is not limited to extending to the side surface 178B and may further extend from the side surface 178B of the recess portion 178R to the flat portion 178PA of the first insulating film 178, which is further outward, as shown in FIG. 3.

The first insulating film 178 may be formed of an organic insulating material. The first insulating film 178 may be a planarization film. The first insulating film 178 may comprise an overcoat material. For example, the first insulating film 178 may include at least one of a polymer having a phenol group, an acrylic polymer, an imide polymer, an aryl ether polymer, a fluorine polymer, a p-xylene polymer, a vinyl alcohol polymer, and a styrene polymer. The first insulating film 178 may have the recess portion 178R and a flat portion 178PA between the recess portions 178R, the flat portion 178PA having a vertical height greater than the bottom surface 178A of the recess portion, to uniformly form a light emitting element ED on the upper surface thereof. The recess portion 178R of the first insulating film 178 includes the flat bottom surface 178A and the side surfaces 178B each having a predetermined taper at each subpixels GSP and RSP. To provide the first insulating film 178, another material may be used as long as it retains organic insulating characteristics.

Meanwhile, the first electrode 150 is disposed on the surface of the first insulating film 178 and the first insulating film 178 is not limited to a transparent material or an opaque material. When the first electrode 150 includes a reflective electrode, light generated in the intermediate layer OL may be reflected by the first electrode 150 and may be emitted upward through the second electrode 160.

As shown in FIG. 3, a second insulating film 176 may be disposed on the lower side of the first insulating film 178 to cover and protect a connecting electrode 140 connecting the first electrode 150 and the lower thin film transistor TFT.

The light emitting display device may further include a third insulating film 175 functioning to protect the upper part of the thin film transistor TFT under the second insulating film 176.

The light emitting display device may further include a fourth insulating film 179 that protects the upper surface of the first electrode 150 formed along the side surface 178B and the bottom surface 178A of the recess portion 178R of the first insulating film 178 and overlaps the flat portion 178PA of the first insulating film 178, the side surface 178B of the recess portion 178R and a portion of the bottom surface 178A extending from the side surface 178B to secure stability at the interface with the intermediate layer OL formed later.

The fourth insulating film 179 may function to cover and protect the upper surface of the first electrode 150 provided along the surface of the recess portion 178R of the first insulating film 178. The fourth insulating film 179 may open the first light emitting portion GA, RA, or BA, and the dummy pattern 152 of each subpixel GSP, RSP, or BSP shown in FIG. 2, and may overlap the second light emitting portion GB, RB, or BB.

The fourth insulating film 179 overlaps the first electrode 150 of the second light emitting portion GB, RB, or BB where light reflection occurs, and may be formed of a material with excellent light transmittance to transmit light from the first electrode 150. The fourth insulating film 179 may be a transparent insulating material or a color pigment material. When the fourth insulating film 179 is a transparent insulating material, the transparent insulating material is not limited to either an inorganic or organic material. The refractive index of the fourth insulating film 179 may be equal to or similar to the average refractive index of the intermediate layer OL. When the fourth insulating film 179 is a color pigment material, the color of the direct light emitted upward from the first electrode 150 disposed in the first light emitting portion GA, RA, or BA may be similar to the color of the side light emitted from the first electrode 150 disposed on the side surface of the recess portion 178R overlapping the second light emitting portion GB, RB, or BB.

The fourth insulating film 179 may be very thin compared to the first insulating film 178 having the recess portion 178R with a predetermined depth to increase the transmittance of the light emitted from the first electrode 150. The thickness of the fourth insulating film 179 may be 1/10 or less to ½ or less of the thickness of the first insulating film 178. For example, when the thickness of the first insulating film 178 is 1 μm to 3 μm, the thickness of the fourth insulating film 179 may be 0.05 μm to 0.5 μm.

The fourth insulating film 179 may, in some cases, completely open the dummy pattern 152, or overlap a part of the edge of the dummy pattern 152. In all cases, in the light emitting display device of the embodiment of the present disclosure, the dummy pattern 152 may directly contact the lower surface of the intermediate layer OL. The dummy pattern 152 may be in a floating state.

The first to fourth insulating films 178, 176, 175, and 179 function to planarize a formation surface of the light emitting element ED, which are also called a “planarization film structure PLN.”

The second insulating film 176 and the third insulating film 175 may include an organic insulating film and/or an inorganic insulating film. Preferably, the second and third insulating films 176 and 175 include a material having excellent flatness. The second insulating film 176 and the third insulating film 175 may include the same material as the first insulating film 178.

The dummy pattern 152 is preferably disposed on the flat portion 178PA of the first insulating film 178 to stabilize the interface characteristics with the intermediate layer OL disposed thereover. That is, the dummy pattern 152 may release charges accumulated in some layers of the intermediate layer OL in the off state of the light emitting element ED of the subpixel. In the light emitting display device according to the embodiment of the present disclosure, the first electrode 150 and the dummy pattern 152 may be formed using the same material in the same process. The dummy pattern 152 may be disposed on the upper flat portion 178PA of the first insulating film 178 and may stabilize and maintain flatness of the formation surfaces of the first and second electron-blocking layers EBL1 and EBL2, and each of the first and second color light emitting layers GEML and REML overlaps the dummy pattern 152. When the dummy pattern 152 is disposed on the upper flat portion 178PA of the first insulating film 178, a sharp step or short circuit of the intermediate layer OL on the dummy pattern 152 may be prevented.

A fourth insulating film 179 thinner than the first insulating film 178 is disposed around the dummy pattern 152. The edge portions of the first and second electron blocking layers EBL1 and EBL2, and the first and second color light emitting layers GEML and REML are disposed along a planar surface over the flat dummy pattern 152 within an open area of the fourth insulating film 179, so that the formation of a charge discharging structure in an off-state is easy and the charge discharging path may be kept short to retain the charge emission effect. The dummy pattern 152 may be a charge emission source which discharges a charge from the first electron blocking layer EBL1 on the dummy pattern 152.

The dummy pattern 152 has the same vertical phase as the vertical phase of the upper flat portion of the first insulating film 178, among the vertical phases of the first electrode 150 in the non-light emitting portion and is spaced apart from the first electrode 150 for independent driving from the first electrode 150. The dummy pattern 152 may have a different potential from the first electrode 150 at the first subpixel in an off state of the first subpixel.

Meanwhile, as shown in FIG. 2, in the light emitting display device according to one embodiment of the present disclosure, the dummy pattern 152 may be spaced apart from the edge of the light emitting portion of the first subpixel and may be provided in the form of a plurality of islands apart from the light emitting portion of the first subpixel. The dummy pattern 152 may be provided along a longitudinal direction of a light emitting portion of the first subpixel.

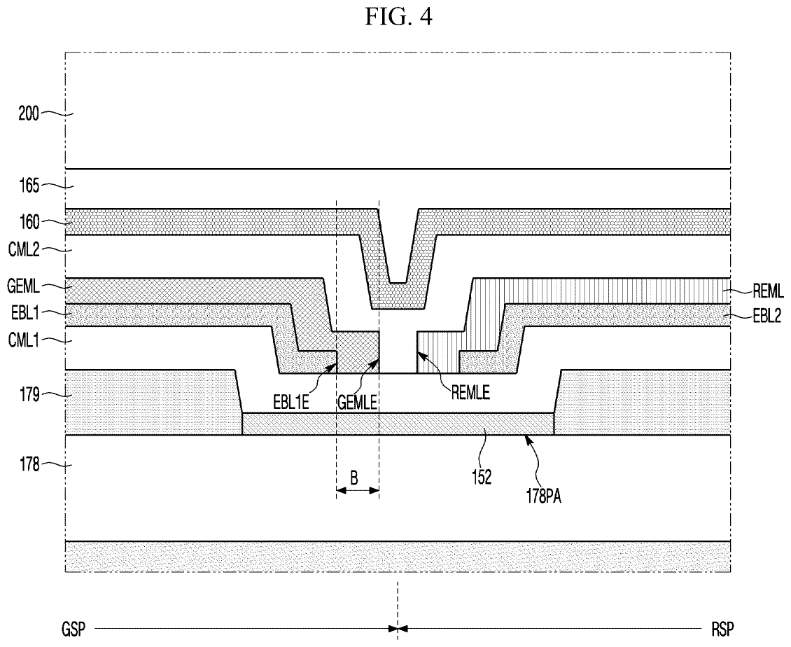

As shown in FIG. 3, the intermediate layer OL may include a first common layer CML1, a color light emitting layer (EML: GEML, REML, BEML), and a second common layer CML2 at each subpixel GSP, RSP, BSP. In the embodiment of FIGS. 3-4, the first common layer CML1 may be disposed on the dummy pattern 152. Edges of the first and second electron blocking layer EBL1 and EBL2, and the first and second color light emitting layers GEML and REML may be disposed on the first common layer CML1.

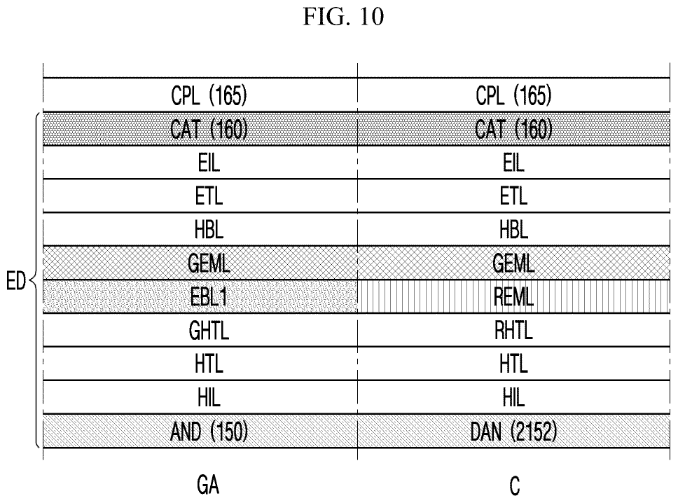

The first common layer CML1 may include a plurality of layers related to hole injection and hole transport. For example, the first common layer CML1 may include a hole injection layer HIL and a hole transport layer HTL. Each or any one of the hole injection layer and the hole transport layer may include a plurality of layers. When each or any one of the hole injection layer and the hole transport layer includes a plurality of layers, each of the layers may separately include a different single material. Alternatively, when each or one of the hole injection layer and the hole transport layer includes a plurality of layers, some layers may contain a single material and other layers may contain a mixture including a plurality of materials. In addition to the first common layer CML1, at least one of a hole transport auxiliary layer GHTL or RHTL (see FIG. 10) and an electron blocking layer EBL that assists hole transport may be further included between the first electrode 150 and the color light emitting layers (EML: GEML, REML, BEML), and the hole transport auxiliary layer GHTL or RHTL, and the electron blocking layer EBL may be provided for the respective subpixels. The hole transport auxiliary layer GHTL or RHTL may be disposed between the hole injection layer HIL and the color light emitting layer (EML: GEML, REML, BEML), and when the first common layer CML1 has a plurality of layers, the hole transport auxiliary layer GHTL or RHTL may be inserted between the plurality of layers. For example, a first transport auxiliary layer may overlap the first color light emitting layer and be disposed between the first electrode and the first electron blocking layer, and a second transport auxiliary layer may overlap the second color light emitting layer and be disposed between the first electrode and the second electron blocking layer.

The second common layer CML2 may include at least one layer related to electron transport and electron injection. For example, the second common layer CML2 may include at least one of a hole blocking layer HBL, an electron transport layer ETL, and an electron injection layer EIL. Each or at least one of the hole blocking layer, the electron transport layer, and the electron injection layer may include multiple layers. When the each or at least one thereof includes a plurality of layers, the layers may each include different single materials. Alternatively, when the each or at least one thereof includes a plurality of layers, some layers may be provided by including a single material and other layers may include a mixture of a plurality of materials. In addition to the second common layer CML2, an electron transport auxiliary layer that assists electron transport may be further included between the color light emitting layer (EML: GEML, REML, BEML) and the second electrode 160, and the electron transport auxiliary layer may be provided separately for each subpixel. When the second common layer CML2 includes a plurality of layers, the electron transport auxiliary layer may be inserted between the layers.

The first common layer CML1 and the second common layer CML2 are provided in common to the subpixels GSP, RSP, and BSP and may be continuously formed between the subpixels GSP, RSP, and BSP. In the light emitting display device according to one embodiment of the present disclosure, each of the first to third subpixels GSP, RSP, and BSP may have the first and second common layers CML1 and CML2 in common.

In addition, the hole transport auxiliary layer and the electron transport auxiliary layer according to one embodiment of the present disclosure may have different thicknesses depending on different microcavity required for the respective subpixels.

The electron blocking layer functions to prevent electrons or excitons from passing from each color light emitting layer to an adjacent hole transport layer. The HOMO energy level difference due to the material difference between the color light emitting layer and the electron blocking layer may be different for the respective subpixels, and the host and dopant contained in the color light emitting layer may have different charge transfer speed, so the electron blocking layer according to one embodiment of the present disclosure may have different thicknesses for the respective subpixels.

As shown in FIG. 3, the intermediate layer OL of the first subpixel GSP may have a stacked structure of a first common layer CML1, a first electron blocking layer EBL1, a first color light emitting layer GEML, and a second common layer CML2. For example, the first common layer CML1 may include a hole injection layer and a hole transport layer, and for example, the second common layer CML2 may include a hole blocking layer, an electron transport layer, and an electron injection layer. In addition, the intermediate layer OL may further include a hole transport auxiliary layer and a first electron blocking layer EBL1 between the hole transport layer and the first color light emitting layer GEML.

The first to third subpixels GSP, RSP, and BSP emit light of different colors and may have optical compensation layers of different thicknesses to adjust the optical distance related to constructive interference for resonance between the first electrode 150 and the second electrode 160 depending on the wavelength of the emission color of each subpixel. For example, the optical compensation layer may be provided in the intermediate layer OL, but may be provided as at least one of a hole transport auxiliary layer and an electron transport auxiliary layer to adjust the vertical phase on the color light emitting layer in the intermediate layer OL. One of the hole transport auxiliary layer and the electron transport auxiliary layer may be omitted from the light emitting element.

In addition, the hole transport auxiliary layer and the electron transport auxiliary layer may have a thickness related to the wavelength of light emitted from each subpixel and thus may be disposed with different thicknesses in the first to third subpixels GSP, RSP, and BSP. In some cases, the hole transport auxiliary layer and the electron transport auxiliary layer may be omitted only in the subpixel of specific color. For example, the hole transport auxiliary layer and the electron transport auxiliary layer may be provided in the first and second subpixels GSP and RSP, and omitted from the third subpixel BSP.

The hole transport auxiliary layer may be disposed, for example, between the hole transport layer of the first common layer CML1 and the color light emitting layer.

The electron transport auxiliary layer may be disposed, for example, between the electron transport layer of the second common layer CML2 and the color light emitting layer.

Each subpixel may further include an electron blocking layer EBL1 or EBL2 between the color light emitting layer and the hole transport auxiliary layer to prevent electrons or excitons from escaping from the color light emitting layer in the direction toward the hole transport layer and to allow electrons and excitons to contribute to light emission within the color light emitting layer.

In addition, a hole blocking layer HBL may be further provided between the color light emitting layer and the electron transport layer to prevent holes from escaping from the color light emitting layer in the direction toward the electron transport layer and to allow holes and excitons to contribute to light emission within the color light emitting layer.

The electron blocking layer and the hole blocking layer may be disposed closest to one side and the other side of the color light emitting layer, respectively. The hole blocking layer may be omitted in some cases.

In the light emitting element ED, the second electrode 160 is commonly provided in a plurality of subpixels GSP, RSP, and BSP provided on the substrate 100 and may be referred to as a “common electrode.” The second electrode 160 may be provided on the substrate 100 in an area larger than the active area AA of FIG. 1. The second electrode 160 may be a transparent electrode or a semi-transparent electrode. For example, when the second electrode 160 is a transparent electrode, the second electrode 160 may include a transparent metal oxide such as ITO, IZO, or ITZO. When the second electrode 160 is a semi-transparent electrode, a metal or metal alloy such as Ag, Mg, or Yb is formed with a thin thickness of 200 Å or less, preferably 150 Å or less, so as to have both resonance within the light emitting element ED and light transmittance through the second electrode 160.

In the embodiment of the present disclosure, the first electron blocking layer EBL1 provided in the first subpixel GSP may have a structural characteristic of having an edge disposed inward from the edge of the first color light emitting layer GEML and thus having a smaller overlapping area with the dummy pattern 152 than the first color light emitting layer GEML.

The first subpixel GSP is a subpixel that emits green light and may have higher relative efficiency in expressing brightness in a light emitting display device than the second and third subpixels RSP and BSP that emit light of red and other colors. Therefore, as shown in FIG. 2, the first subpixel GSP may have a higher arrangement ratio than the second and third subpixels RSP and BSP.

In a light emitting display device, when the relative efficiency of the first subpixel GSP is higher than that of the other color subpixels, the luminance dependency of the first subpixel GSP is high. Therefore, in order to control the luminance sensitivity of the light emitting element in the first subpixel GSP, the first electron-blocking layer EBL1 of the first subpixel GSP having a lower (deeper) HOMO energy level than horizontally adjacent subpixels is provided to adjust the threshold voltage Vth of the light emitting element required for switching from the off state to the on state to a predetermined level or higher and thereby control the capacitance of the light emitting element of the first subpixel GSP.

Therefore, the first subpixel GSP may have the first electron-blocking layer EBL1 having a lower (deeper) HOMO energy level to control the threshold voltage Vth for the on state of the light emitting element and the capacitance of the light emitting element. Meanwhile, rapid discharge of the charges accumulated in the light emitting element during switching from the on-state to the off-state is required to clearly render black of the off-state. However, during the charge discharge process, the HOMO energy level of the first electron blocking layer EBL1 between the first color light emitting layer GEML and the first electrode 150 is very low, so there is a high probability that the holes moving from the first color light emitting layer GEML to the first electrode 150 are trapped at the interface between the first electron blocking layer and the first color light emitting layer. This means that normal black is not immediately rendered after switching to the off-state.

As such, for example, when a specific area of the light emitting display device is observed as gray and another area around the specific area is observed as black, with respect to holes trapped in the first electron blocking layer, the area that should be expressed as black may be observed as gray in the previous frame during moving from the specific area to the other area. This phenomenon is called “screen dragging.” In particular, the large difference in HOMO energy level between the first electron blocking layer having a low HOMO energy level and the first color light emitting layer causes the holes accumulated at the interface between the first electron blocking layer and the first color light emitting layer to not be discharged or to be discharged with a delay in the off state, thus resulting in delay of the operation of the light emitting element.

Structurally, among the layers between the first electrode 150 and the first color light emitting layer GEML in the first subpixel GSP, the first electron blocking layer EBL1 has the lowest HOMO energy level.

The light emitting display device according to the embodiment of the present disclosure is provided with a dummy pattern 152 on a flat portion 178PA of the first insulating film 178 around the first subpixel GSP, and has a configuration in which the edge of the first color light emitting layer GEML protrudes more than the edge of the first electron blocking layer EBL1 on the dummy pattern 152, so that the overlapping area of the first color light emitting layer GEML and the dummy pattern 152 is larger than the overlapping area of the first electron blocking layer EBL1 and the dummy pattern 152. Therefore, a direct vertical discharging path of holes is formed between the first common layer CML1 and the first color light emitting layer GEML on the dummy pattern 152. Here, the first common layer CML1 has a higher HOMO energy level than the first electron blocking layer EBL1. That is, there is an HOMO energy level difference between the first color light emitting layer GEML and the first common layer CML1, which is smaller than the HOMO energy level difference between the first color light emitting layer GEML and the first electron blocking layer EBL1 on the dummy pattern 152, which is a path through which charges are discharged. That is, in the light emitting display device according to the embodiment of the present disclosure, during switching from the on-state to the off-state, a direct discharging path of holes is formed from the first color light emitting layer GEML through the first common layer CML1 toward the dummy pattern 152, and further, in the path through which holes are transferred from the first color light emitting layer GEML to the dummy pattern 152 in the off state, the difference in HOMO energy levels at each interface is reduced to facilitate charge passing, thereby preventing a delay in the discharge time of the charges and poor visibility such as screen dragging.

In the embodiment of the present disclosure, different edges may be imparted to the first electron blocking layer EBL1 and the first color light emitting layer GEML by forming the first color light emitting layer GEML and the first electron blocking layer EBL1 using different deposition masks. Accordingly, the second subpixel RSP apart from the first subpixel GSP with the dummy pattern 152 therebetween may include the second electron blocking layer EBL2 spaced apart from the first electron blocking layer EBL1. The first and second electron blocking layers EBL1, and EBL2 may be located in the same layer such that they are spaced apart from each other. The first and second electron blocking layers EBL1 and EBL2 may be formed in areas defined by the same deposition mask.

Here, a second color light emitting layer REML may be provided on the dummy pattern 152 around the second subpixel RSP to cover the edge of the second electron blocking layer EBL2. In this case, an interface is formed at the edge of the second color light emitting layer REML that directly contacts the first common layer CML1 without the second electron blocking layer EBL2, so that the interface may be reduced in the charge discharging path and the energy barrier may be reduced at the interface of the charge discharging.

Meanwhile, the third subpixel BSP may have the third electron blocking layer at a position spaced apart from the first and second electron blocking layers EBL1, and EBL2 of the first and second subpixels GSP and RSP, or may have an electron blocking layer that extends horizontally from either the first electron blocking layer EBL1 or the second electron blocking layer EBL2.

In the embodiment of the present disclosure, the first and second electron blocking layers EBL1 and EBL2 are characterized in that they are spaced apart from each other on the dummy pattern 152 and the first color light emitting layer GEML directly contacts the first common layer CML1 on the lower side thereof through the first or second electron blocking layer EBL1 or EBL2 regions.

The color light emitting layer GEML, REML, BEML of each light emitting unit GEM, REM, BEM may be adjacent to the hole transport layer among the first common layers CML1.

When each subpixel GSP, RSP, BSP has a separate electron blocking layer, the electron blocking layer and the hole transport auxiliary layer of each subpixel may be patterned with the same deposition mask. In this case, the electron blocking layer and the hole transport auxiliary layer at each subpixel may have the same edge. When the hole transport auxiliary layer and the electron blocking layer are patterned with the same deposition mask, there is an advantage in that the number of deposition masks having micro-openings may be reduced during formation of the intermediate layer OL of the light emitting element. The hole transport auxiliary layer and the electron blocking layer may each include a hole transport material, but may be formed of different materials.

Meanwhile, in the light emitting display device according to the embodiment of the present disclosure, the first electron-blocking layer EBL1 provided in the first subpixel GSP has an edge on the dummy pattern 152 and the first color light emitting layer GEML is disposed to surround the upper surface and the edge of the first electron-blocking layer EBL1 on the upper surface of the first electron-blocking layer EBL1. Therefore, the first electron-blocking layer EBL1 may be in contact with the hole transport layer of the first common layer CML1 with respect to the dummy pattern 152. In order to facilitate control of the threshold voltage of the light emitting element and control of the electrostatic capacitance, the first electron-blocking layer EBL1 may be formed using a material having a large energy band gap and a low HOMO energy level. For example, the HOMO energy level difference between the first color light emitting layer GEML and the first electron blocking layer EBL1 may be 0.5 eV or more and 1.2 eV or less.

The first electrode 150 may comprise an extension portion extending from the side surface 178B of the recess portion 178R to an upper surface of the first insulating film 178, and the extension portion of the first electrode 150 and the dummy pattern 152 may have a same vertical phase. The first electrode 150 disposed in a part of the flat portion 178PA of the first insulating film 178 may have the same vertical phase as the dummy pattern 152. The first electrode 150 located in the flat portion 178PA of the first insulating film 178 may be connected to the thin film transistor TFT disposed thereunder through a contact hole penetrating the first insulating film 178 in the flat portion 178PA of the first insulating film 178. Here, when the contact hole is provided in the flat portion 178PA of the first insulating film 178, connection to the lower thin film transistor TFT may be possible without interference with the light emitting portion.

When light generated in the intermediate layer OL of the light emitting element ED is directed toward the first electrode 150, it may be reflected from the surface of the first electrode 150, re-reflected upward and emitted through the second electrode 160. In the area of the first electrode 150 located on the bottom surface 178A of the recess portion 178R, light incident vertically or substantially vertically from the intermediate layer OL to the surface of the first electrode 150 may be reflected, returned upward and emitted through the second electrode 160 vertically or substantially vertically, and in the area of the first electrode 150 located on the side surface 178B of the recess portion 178R, light incident radially from the intermediate layer OL may contact the surface of the first electrode 150 and be deflected toward the first light emitting portion GA, RA, BA, or the second light emitting portion GB, RB, or BB, so that light may be emitted upward.

In a structure where the pixel defining film covers the edge of the first electrode, only the area of the first electrode opened by the pixel defining film is used as a light emitting portion. On the other hand, in the light emitting display device according to an embodiment of the present disclosure, the first electrode 150 is also provided on the side surface 178B of the recess portion 178R of the first insulating film 178, so that light may be extracted from the side surface of the first insulating film 178, thereby providing an advantage of improved luminous efficacy. For example, when the pixel defining film has a light emitting portion as large as the area of the first light emitting portions GA, RA, or BA in the structure where the pixel defining film covers the edge of the first electrode, as in the light emitting display device according to an embodiment of the present disclosure, advantageously, the light emitting area may be increased as large as the area of the second light emitting portion GB, RB or BB. Accordingly, the light emitting display device of the present disclosure may have effects of increasing the light emitting area using at least a part of the overlapping area with the first electrode 150 in the pixel defining film or the first insulating film as a second light emitting portion GB, RB, or BB when the same voltage is applied to the first electrode 150, solving the phenomenon in which light emission is limited, and improving luminous efficacy.

The substrate 100 on which each subpixel is disposed may be formed of a single or multiple layers. The substrate 100 may include at least one of a glass substrate, a plastic film, and a metal plate having a predetermined supporting force. The substrate 100 may be formed of a flexible material. For example, as shown in FIG. 3, when the substrate 100 is formed of multiple layers 101, 102, 103, it may have a stacked structure of a first organic film 101, an inorganic insulating layer 102, and a second organic film 103. The first organic film 101 on the outermost side may prevent the introduction of external impurities and have a protective function. The second organic film 103 may function to planarize the formation surface of the internal array structure and to prevent charge transfer or impurity transfer from the outside to the inside. The inorganic insulating layer 102 between the first and second organic films 101 and 103 may function to prevent moisture diffusion between the first and second organic films 101 and 103.

A fifth insulating film 171 may be provided on the substrate 100. The fifth insulating film 171 may function as a buffer layer or an active buffer layer. The buffer layer and the active buffer layer may protect the wiring and the active layer included in the internal array from the lower side. The fifth insulating film 171 may have multiple layers.

A thin film transistor TFT and a storage capacitor Cs may be disposed on the fifth insulating film 171.

A light-blocking layer 111 may be provided on the fifth insulating film 171 to prevent light from being transmitted from below to the active layer 112 of the thin film transistor TFT.

A sixth insulating film 172 may be disposed between the light-blocking layer 111 and the active layer 112.

The thin film transistor TFT may be disposed on each of a plurality of subpixels on the sixth insulating film 172. For example, the thin film transistor TFT may include an active layer 112, a gate electrode 120 overlapping the active layer 112 with a seventh insulating film 173 interposed therebetween, and a first source/drain electrode 131 and a second source/drain electrode 132 connected to both sides of the active layer 112.

For example, a storage capacitor Cs may include a first storage electrode 113 and a second storage electrode 121 overlapping each other. At least one of the first and second storage electrodes 113 and 121 may be formed of the same material as the active layer 112, and the other may include the same material as the gate electrode 120, the first and second source/drain electrodes 131 and 132, and the light-blocking layer 111.

The seventh insulating film 173 between the active layer 112 and the gate electrode 120 may function as a gate insulating film.

The active layer 112 may include, for example, a silicon-based or oxide semiconductor. The silicon-based semiconductor may include crystalline and/or amorphous silicon. The oxide semiconductor may include at least one of gallium oxide, tin oxide, zinc oxide, indium oxide, iron oxide, and indium-gallium-zinc oxide. The oxide semiconductor layer may be formed of multiple layers having different materials or different material composition ratios. Each subpixel may include multiple thin film transistors and the thin film transistors may be disposed on different layers. For example, the first thin film transistor may be formed as a silicon-based active layer and may be closer to the substrate 100, and the second thin film transistor may be formed as an oxide semiconductor active layer above the first thin film transistor.

The active layer 112 may include a channel region overlapping the gate electrode 120 and a source/drain region connected to each of the first and second source/drain electrodes 131 and 132.

The seventh insulating film 173 may be selectively disposed corresponding to the channel region of the active layer 112 and may be provided over the entire surface of the substrate 100 excluding the region through which the first and second source/drain electrodes 131 and 132 penetrate. The seventh insulating film 173 may function to insulate the active layer 112 from the gate electrode 120. The seventh insulating film 173 may be formed of an inorganic insulating material and may be formed as, for example, a silicon oxide (SiOx) film, a silicon nitride (SiNx) film, a silicon oxynitride (SiOxNy) film, or a multilayer film thereof.

A gate electrode 120 may be formed on the seventh insulating film 173. The gate electrode 120 may be disposed to face the active layer 112 with the seventh insulating film 173 interposed therebetween.

An eighth insulating film 174 may be formed on the gate electrode 120 to cover and protect the gate electrode 120. In addition, the eighth insulating film 174 may function to protect at least one electrode of the thin film transistor TFT and the active layer 112. The eighth insulating film 174 may be formed of an inorganic insulating material. For example, the eighth insulating film 174 may be formed as a silicon oxide (SiOx) film, a silicon nitride (SiNx) film, a silicon oxynitride (SiOxNy) film, or a multilayer film thereof.

A first source/drain electrode 131 and a second source/drain electrode 132 may be disposed on the eighth insulating film 174. The eighth insulating film 174 and the seventh insulating film 173 may have contact holes to contact the first and second source/drain electrodes 131 and 132 at both ends of the active layer 112 and the corresponding areas may be removed.

The gate electrode 120 and the first and second source/drain electrodes 131 and 132 may each be formed as a single layer or multiple layers.

When the gate electrode 120 and the first and second source/drain electrodes 131 and 132 are single layers, they may be formed of one selected from the group consisting of molybdenum (Mo), aluminum (Al), chromium (Cr), gold (Au), titanium (Ti), nickel (Ni), neodymium (Nd), and copper (Cu), and an alloy thereof. In addition, when the gate electrode 120 and the first and second source/drain electrodes 131 and 132 include multiple layers, they may include double layers of molybdenum/aluminum-neodymium, molybdenum/aluminum, titanium/aluminum, or copper/molybdenum-titanium. Alternatively, the gate electrode 120 and the first and second source/drain electrodes 131 and 132 may include triple layers of molybdenum/aluminum-neodymium/molybdenum, molybdenum/aluminum/molybdenum, titanium/aluminum/titanium, or molybdenum/copper/molybdenum.

However, the configuration of the gate electrode 120 and the first and second source/drain electrodes 131 and 132 is not limited thereto, and the gate electrode 120 and the first and second source/drain electrodes 131 and 132 and the second storage electrode 121 may include multiple layers formed of one or more selected from the group consisting of molybdenum (Mo), aluminum (Al), chromium (Cr), gold (Au), titanium (Ti), nickel (Ni), neodymium (Nd), and copper (Cu), and an alloy thereof.

The fifth to eighth insulating films 171, 172, 173, and 174 may each be formed as inorganic insulating films. The inorganic insulating film may be, for example, formed as at least one of a silicon oxide film, a silicon nitride film, and a silicon oxynitride film. The fifth to eighth insulating films 171, 172, 173, and 174 are also called an “array insulating film structure INL” in comparison with the upper planarization film structure PLN. At least one of the fifth to eighth insulating films 171, 172, 173, and 174 may be formed as multiple layers.

A connecting electrode 140 connected to the second source/drain electrode 132 may be further included on the third insulating film 175 covering and protecting the thin film transistor TFT. The connecting electrode 140 is connected to the first electrode 150.

The connecting electrode 140 may be provided as multiple layers formed of one or more selected from the group consisting of molybdenum (Mo), aluminum (Al), chromium (Cr), gold (Au), titanium (Ti), nickel (Ni), neodymium (Nd), and copper (Cu), and an alloy thereof. However, the embodiments of the present disclosure are not limited thereto. In some cases, the connecting electrode 140 may be omitted. When the connecting electrode 140 is omitted, one of the first and second source/drain electrodes 131 and 132 may be directly connected to the first electrode 150.

An encapsulation layer 200 protecting the light emitting element ED may be further provided on the second electrode 160. The encapsulation layer 200 may be a single layer or multiple layers. When the encapsulation layer 200 is provided as a multiple layer, it may be formed by laminating at least one inorganic encapsulation film and at least one organic encapsulation film. The inorganic encapsulation film may prevent moisture penetration and the organic encapsulation film may cover particles and flatten the surface. The organic encapsulation film may be located inside the inorganic encapsulation film on a plane. In this case, the inorganic encapsulation film may prevent moisture penetration to the side.

A touch unit including a first touch electrode 304a, 304b and a second touch electrode 305 may be provided on the encapsulation layer 200. The first touch electrode 304a, 304b and the second touch electrode 305 may be disposed in different directions and the number of the first touch electrodes 304a, 304b and the second touch electrodes 305 may be at least two.

For example, the first touch electrode 304a, 304b may transmit a touch control signal and the second touch electrode 305 may receive touch information and ultimately transmit the touch information to the touch control unit. In another embodiment, the first touch electrode 304a, 304b may receive touch information and the second touch electrode 305 may transmit a touch control signal.

The touch unit may include a touch buffer film 301 on the encapsulation layer 200, a bridge electrode 302 provided on the touch buffer film 301, a touch interlayer insulating film 303 provided on the bridge electrode 302, a first touch electrode 304a, 304b connected to the bridge electrode 302 through a contact hole in the touch interlayer insulating film 303 and disposed on the touch interlayer insulating film 303, and a second touch electrode 305 spaced apart from the first touch electrode 304a, 304b and disposed on the touch interlayer insulating film 303.

The first touch electrode 304a, 304b and the second touch electrode 305 correspond to the non-light emitting portion of each subpixel and may not interfere with the light path when light generated from the light emitting element ED is emitted above the second electrode 160. At least one of the first touch electrode 304a, 304b and the second touch electrode 305 may overlap the dummy pattern 152.

The outermost part of the touch unit may be provided with a touch protection film 310 that protects the first and second touch electrodes 304a, 304b, 305. In addition to the touch protection film 310, an optical film or a protective film may be further provided on the touch protection film 310. In some cases, the optical film or the protective film may replace the function of the touch protection film.

The touch buffer film 301 and the touch interlayer insulating film 303 may be inorganic insulating films. In some cases, at least one of the touch buffer film 301 and the touch interlayer insulating film 303 may include an organic insulating film.

The touch protection film 310 includes an organic insulating film and may function to prevent external physical impact from being transmitted to the inside and protect the touch unit. The touch protection film 310 may be thicker than each of the touch buffer film 301 and the touch interlayer insulating film 303 and may sufficiently buffer external impact.

A cover layer or cover film (not shown) may be further included on the touch protection film 310.

Although not shown in the drawing, a color filter unit including a color filter (not shown) and a black matrix (not shown) may be provided on the encapsulation layer 200. The black matrix corresponds to a non-light emitting portion of each subpixel and may not interfere with the light path when light generated from the light emitting element ED is emitted above the second electrode 160. Light generated from the light emitting element ED may be emitted through the color filter. The black matrix may overlap the dummy pattern 152. When the color filter unit is located on the touch unit, the black matrix may overlap the first touch electrode 304a, 304b and the second touch electrode 305. Accordingly, the black matrix may minimize external light reflected by the dummy pattern 152 or the first touch electrodes 304a, 304b and the second touch electrodes 305.

Hereinafter, in the light emitting element, the significance of the light emitting display device according to the embodiments of the present disclosure will be specifically examined by comparing the structure within the light emitting portion of the subpixel with the area where the dummy pattern is located between adjacent subpixels.

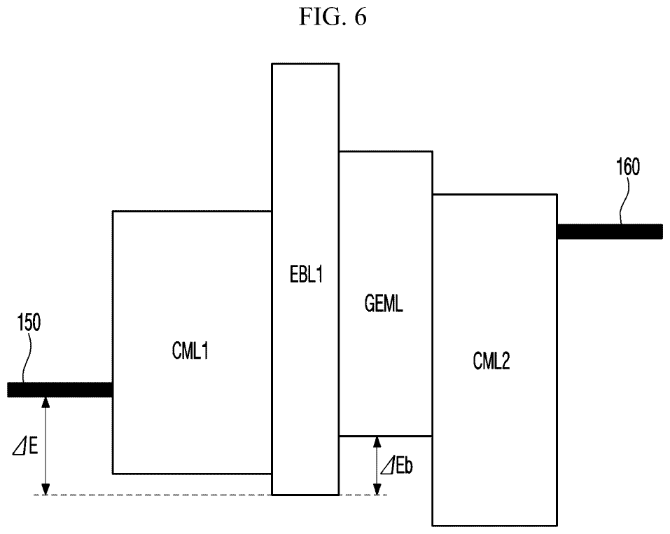

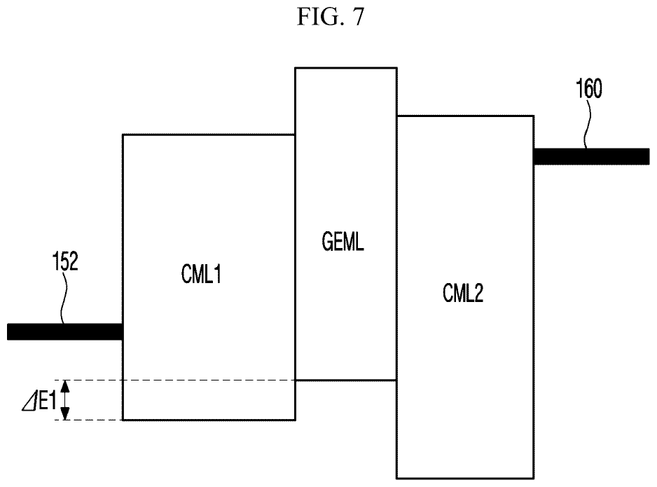

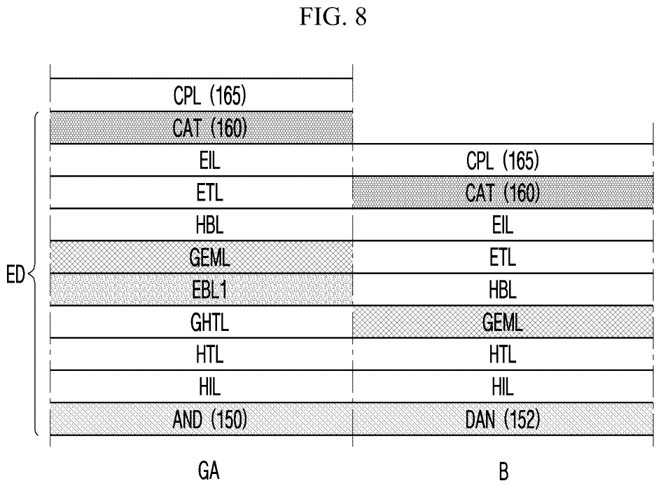

FIG. 4 is a cross-sectional view illustrating a first embodiment of the structure of the region A of FIG. 3. FIG. 6 is an energy band diagram of a light emitting element within the light emitting portion according to one embodiment. FIG. 7 is an energy band diagram between the dummy pattern of the region B of FIG. 4 and the second electrode. FIG. 8 is a cross-sectional view illustrating an example of the stacked structure of the region B and the light emitting portion of the first embodiment.

As shown in FIG. 4, in the light emitting display device according to the first embodiment of the present disclosure, considering the configuration of the upper portion of the dummy pattern 152 in the area outside the first electron blocking layer EBL1, a first common layer CML1, a first color light emitting layer GEML, a second common layer CML2, and a second electrode 160 are sequentially stacked on the dummy pattern 152. As shown in FIG. 4, a capping layer 165 may be provided on the second electrode 160. An encapsulation layer 200 may be provided to cover the capping layer 165.

As shown in FIG. 8, the first common layer CML1 may include a hole injection layer HIL, a hole transport layer HTL, and a hole transport auxiliary layer GHTL, and the second common layer CML2 may include a hole blocking layer HBL, an electron transport layer ETL, and an electron injection layer EIL.

In addition, as shown in FIG. 8, the hole transport auxiliary layer GHTL and a first electron blocking layer EBL1 may be further included between the hole transport layer and the first color light emitting layer GEML.

The dummy pattern 152 may be disposed on the flat portion 178PA of the first insulating film 178 and may be exposed by the fourth insulating film 179. Although not shown in the drawing, an end of the dummy pattern 152 may be partially covered by the fourth insulating film 179. The dummy pattern 152 may be formed simultaneously with the formation of the first electrode 150. The dummy pattern 152 may include the same material as the first electrode 150. When the first electrode 150 includes a stacked configuration of a reflective electrode layer and a transparent electrode layer, the dummy pattern 152 may have multiple layers identical to the first electrode 150, or may include only a transparent electrode layer.

When the first and second common layers CML1, and CML2 each include multiple layers, referring to FIG. 8, the stacked structure of the light emitting element ED in the first light emitting portion GA in the first subpixel in the light emitting display device according to the first embodiment of the present disclosure is compared with the stacked structure in the region of “B” of FIG. 4, as follows.

As shown in FIG. 8, in the light emitting display device according to the first embodiment of the present disclosure, the light emitting element ED in the first light emitting portion GA in the first subpixel may sequentially be provided with a hole injection layer HIL, a hole transport layer HTL, a hole transport auxiliary layer GHTL, a first color light emitting layer GEML, a hole blocking layer HBL, an electron transport layer ETL, an electron injection layer EIL, a second electrode (160, CAT), and a capping layer (165, CPL) on the first electrode (150, AND).

In the light emitting display device according to the first embodiment of the present disclosure, in the region of “B” of FIG. 4, a hole injection layer HIL, a hole transport layer HTL, a first color light emitting layer GEML, a hole blocking layer HBL, an electron transport layer ETL, an electron injection layer EIL, a second electrode (160, CAT), and a capping layer (165, CPL) may be sequentially provided on a dummy pattern (152, DAN) in a non-light emitting portion around the first subpixel as shown in FIG. 8.

Meanwhile, in the light emitting display device according to the first embodiment of the present disclosure, the second color light emitting layer REML provided in the second subpixel RSP adjacent to the first subpixel GSP is illustrated as having a shape that surrounds the edge of the second electron blocking layer EBL2, but this is provided merely as an example and it is not an essential configuration that the second electron blocking layer EBL2 and the second color light emitting layer REML overlap the dummy pattern 152. That is, in the light emitting display device according to the first embodiment, the second electron-blocking layer EBL2 and the second color-emitting layer REML may not overlap the dummy pattern 152. In the light emitting display device according to the first embodiment of the present disclosure, the dummy pattern 152 secures a vertical charge discharging path of holes through a portion where the first color-emitting layer GEML directly contacts the first common layer CML1 on the outside of the first electron-blocking layer EBL1 in the off state, so that the holes accumulated in the first electron-blocking layer EBL1 may be easily discharged to the outside of the light emitting element ED.

The capping layer (165, CPL) primarily protects the light emitting element and may function to impart a microcavity resonance effect to the light emitted through the second electrode (160, CAT) to thereby improve the light emitting efficiency.

In the example of FIG. 8, the hole blocking layer HBL may be omitted.

In the example of FIG. 8, the hole transport auxiliary layer GHTL is omitted from the first subpixel GSP and the resonance effect within the light emitting element ED may be different from that of the second and third subpixels RSP and BSP by adjusting the thickness of the first color light emitting layer GEML.

As shown in FIGS. 3 and 4, in the light emitting portion GA, the first color light emitting layer GEML directly completely overlaps the first electron blocking layer EBL1 and thus has a larger overlapping area with the dummy pattern 152 than the first electron blocking layer EBL1. As shown in FIG. 6, the first subpixel GSP includes the first electron-blocking layer EBL1 having an HOMO energy level that is lower (deeper) than that of horizontally adjacent subpixels, so that the threshold voltage Vth of the light emitting element required for switching from the off state to the on state is adjusted to a predetermined level or higher, and the electrostatic capacitance of the light emitting element of the first subpixel GSP may be controlled. The HOMO energy level of the first electron-blocking layer EBL1 has a difference of ΔE from the work function of the first electrode 150 and this is related to the threshold voltage Vth of the first light emitting portion GA of the first subpixel. When the first electron-blocking layer EBL1 has a low HOMO energy level, it may have a large HOMO energy level difference ΔEb from the HOMO energy level of the first color light emitting layer GEML. As the difference in HOMO energy levels between the first color light emitting layer GEML and the first electron blocking layer EBL1 increases, the probability that holes will accumulate at the interface between the first color light emitting layer GEML and the first electron blocking layer EBL1 increases during switching from the on-state to the off-state.

As shown in FIGS. 4, 6 to 8, the light emitting display device according to the first embodiment of the present disclosure further includes a dummy pattern 152 formed of the same material as the first electrode 150 on a part of the non-light emitting portion, to easily release holes from the first color light emitting layer GEML directly contacting the first common layer CML1 outside the edge EBL1E of the first electron blocking layer EBL1 when switching from the on-state to the off-state. When switching from the on-state to the off-state, holes may be easily released directly from the first common layer CML1 in the region where the first color light emitting layer GEML contacts the first common layer CML1 with a small HOMO energy level difference ΔE1 therebetween, and thus holes may be easily released to the overlapping dummy pattern 152.

Here, the HOMO energy level difference ΔE1 between the first color light emitting layer GEML and the first common layer CML1 in the non-overlapping region with the first and second electron blocking layers EBL1 and EBL2 on the dummy pattern 152, as shown in FIG. 7, may be smaller than the HOMO energy level difference ΔEb between the first color light emitting layer GEML and the first electron blocking layer EBL1 on the first electrode of the first subpixel, as shown in FIG. 6.

The holes trapped at the interface between the first electron blocking layer EBL1 and the first color light emitting layer GEML in the light emitting element ED of the first subpixel GSP may also be easily transferred to the dummy pattern 152 because they are transferred to the first color light emitting layer GEML and/or the first common layer CML1 through the edge EBL1E of the first electron blocking layer EBL1.

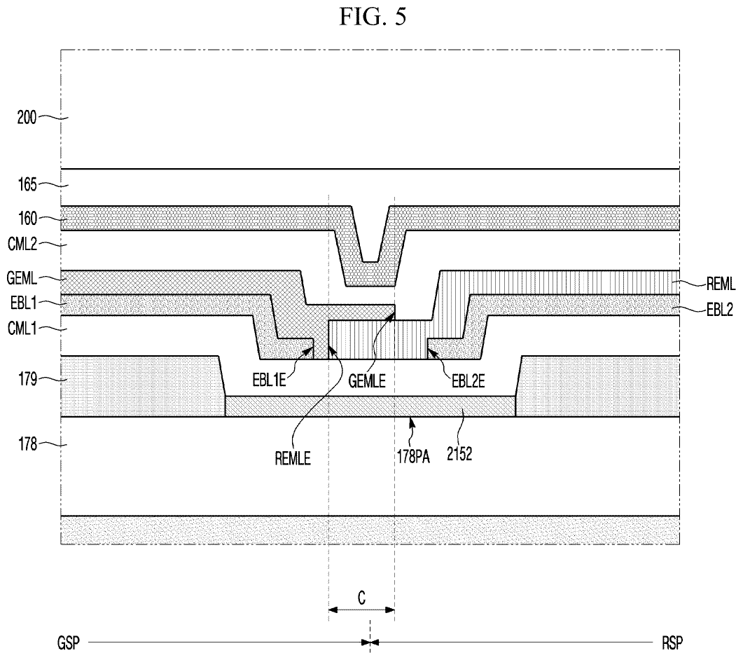

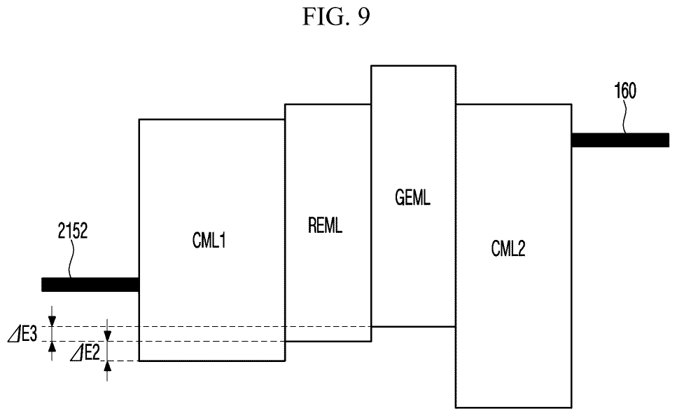

FIG. 5 is a cross-sectional view illustrating a second embodiment of the structure of the region A of FIG. 3. FIG. 9 is an energy band diagram between the dummy pattern of the region C of FIG. 5 and the second electrode. FIG. 10 is a cross-sectional view illustrating an example of the stacked structure of the region C and the light emitting portion of the second embodiment.

As shown in FIG. 5, in the light emitting display device according to the second embodiment of the present disclosure, considering the configuration of the upper portion of the dummy pattern 2152 in the area outside the first electron blocking layer EBL1, a first common layer CML1, a second color light emitting layer REML, a first color light emitting layer GEML, a second common layer CML2, and a second electrode 160 are sequentially stacked on the dummy pattern (2152, DAN). The difference from the configuration shown in FIG. 4 is that the second color emitting layer REML further extends toward the first subpixel GSP and thus further has an overlapping area with the first color light emitting layer GEML on the dummy pattern 2152.

Here, the edges EBL1E, EBL2E of the first electron blocking layer EBL1 of the first subpixel GSP and the second electron blocking layer EBL2 of the second subpixel RSP are spaced apart from each other and the first color light emitting layer GEML and the second color light emitting layer REML overlap within the space between the edges EBL1E, EBL2E of the first and second electron blocking layers EBL1, and EBL2.

In this case, the edge GEMLE of the first color light emitting layer GEML may overlap the non-light emitting portion of the second subpixel RSP, and the edge REMLE of the second color light emitting layer REML may overlap the non-light emitting portion of the first subpixel GSP.

As the overlapping area between the first color light emitting layer GEML and the second color light emitting layer REML on the dummy pattern 2152 increases, holes are easily released in the order of the first color light emitting layer GEML, the second color light emitting layer REML, the first common layer CML1, and the dummy pattern 2152 during switching from the on-state to the off-state, as shown in FIG. 9. A second color light emitting layer REML is provided between the first color light emitting layer GEML and the first common layer CML1, so that an HOMO energy level difference ΔE3 between the first color light emitting layer GEML and the second color light emitting layer REML and an HOMO energy level difference ΔE2 between the second color light emitting layer REML and the first common layer CML1 occur sequentially, so that, when holes are directed from the first color light emitting layer GEML to the dummy pattern 2152, the energy barrier is not great, thus facilitating hole release.

Here, the first electron blocking layer EBL1 or the second electron blocking layer EBL2 may have a lower HOMO energy level than each of the first common layer CML1 and the first color light emitting layer GEML and the second color light emitting layer REML. In addition, the HOMO energy level of the second color light emitting layer REML may be lower than that of the first color light emitting layer GEML.

Meanwhile, as shown in FIG. 10, the first color light emitting layer GEML and the second color light emitting layer REML may further include a hole transport auxiliary layer GHTL or RHTL on the lower sides thereof, respectively. Alternatively, in some cases, although the hole transport auxiliary layer GHTL is provided in the first light emitting portion GA, the hole transport auxiliary layer GHTL may be omitted on the dummy pattern 2152. In the embodiment of the present disclosure, the first color light emitting layer GEML vertically contacts the first electron blocking layer EBL1 at least in the first and second light emitting portions GA, GB, so the hole transport auxiliary layer GHTL of the first subpixel GSP may be disposed lower than the first electron blocking layer EBL1. In the light emitting display device according to the second embodiment, the second color light emitting layer REML is disposed so as to cover the edge EBL2E of the second electron blocking layer EBL2 on the dummy pattern 2152, and the first color light emitting layer GEML is provided so as to cover the edge REMLE of the second color light emitting layer REML. Here, in the region C between the edges EBL1E, EBL2E of the first and second electron blocking layers EBL1, and EBL2 on the dummy pattern 2152, a first common layer CML1, a second color light emitting layer REML, a first color light emitting layer GEML, a second common layer CML2, a second electrode 160, and a capping layer 165 are sequentially stacked on the dummy pattern 2152.

Description of the same configuration in FIG. 10 as the first embodiment is omitted.

As such, a region in which the first electron blocking layer having a large HOMO energy level difference from the first color light emitting layer is omitted from the dummy pattern 152, 2152 in the first embodiment and the second embodiment is provided, so that direct contact between the first color light emitting layer and the first common layer or the second color light emitting layer having a small HOMO energy level difference is possible on the dummy pattern 152, 2152, to facilitate release of holes from the first color light emitting layer to the dummy pattern when switched to the off state.

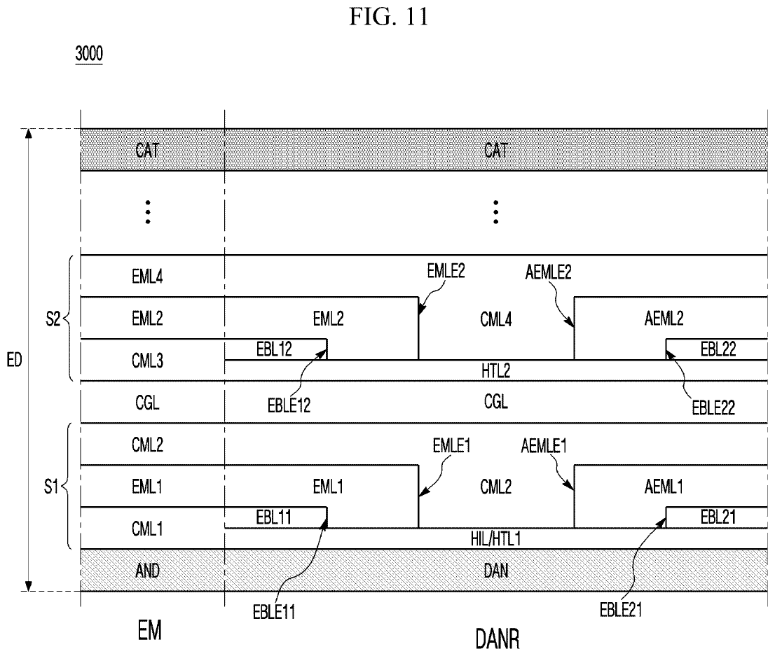

FIG. 11 is a cross-sectional view illustrating an example of a stacked structure of a light emitting portion and a dummy pattern region of a light emitting display device according to the third embodiment of the present disclosure.

As shown in FIG. 11, the light emitting display device 3000 according to the third embodiment of the present disclosure has a configuration in which at least one of the light emitting elements ED of the first to third subpixels GSP, RSP, and BSP includes two or more stacks.

Each stack of the light emitting elements ED may be distinguished from a charge generation layer CGL. The charge generation layer CGL may be formed by, for example, stacking a p-type charge generation layer and an n-type charge generation layer.

Each stack S1, S2 may include a first common layer CML1, CML3 related to hole injection and/or hole transport, a light emitting layer (EML1, EML2, . . . ), and a second common layer CML2, CML4 related to electron transport and/or electron injection. When the light emitting element ED has three or more stacks, a charge generation layer and another stack may be further included between the second stack S2 and the second electrode CAT.

Here, the first common layer CML1, CML3 related to hole transport may include a hole transport layer HTL1, HTL2, and an electron blocking layer EBL. The first common layer CML1 of the first stack S1 may further include a hole injection layer HIL compared to the first common layer CML3 of the second stack S2. The hole injection layer HIL and the hole transport layer HTL may be provided in common for a plurality of subpixels. In this case, the first electrode AND and the dummy pattern DAN may be in contact with the hole injection layer.

The second common layer CML2, CML4 related to electron transport may include a hole blocking layer and an electron transport layer. The second common layer closest to the second electrode CAT may further include an electron injection layer.

Although multiple stacks are included in the light emitting portion EM of a subpixel, a dummy pattern DAN may be provided in a non-light emitting portion, and a first electron-blocking layer EBL11, EBL12 of a first common layer CML1, CML3 related to hole transport among the stacks may be spaced apart from a second electron-blocking layer EBL21, EBL22 of an adjacent subpixel, and a light emitting layer EML1, EML2 of each stack may be provided to cover an edge EBLE11, EBLE12 of the first electron-blocking layer EBL11, EBL12 having a low HOMO energy level.

The edge of the second electron-blocking layer EBL21, EBL22 may overlap the color light emitting layer AEML1, AEML2 of the adjacent subpixel. The edges AEMLE1, AEMLE2 of the color light emitting layers AEML1, AEML2 of the adjacent subpixels may be spaced apart from the edges EMLE1, EMLE2 of the light emitting layers EML1, EML2 as illustrated. Alternatively, without being limited to the illustrated example, the edges AEMLE1, AEMLE2 of the color light emitting layers AEML1, AEML2 of the adjacent subpixels may further extend to overlap the light emitting layers EML1, EML2. The color light emitting layer may be disposed in two or more layers at the first subpixel and the two or more layers may be disposed to overlap each other with a charge generation layer CGL therebetween.

FIG. 11 illustrates an example in which the light emitting layers EML1, EML2 are provided to cover the edges EBLE11, EBLE12 of the electron blocking layers EBL11, EBL12 of both the first stack S1 and the second stack S2 divided by the charge generation layer CGL, but the embodiment of the present disclosure is not limited thereto. For example, only the edge EBLE11 of the electron blocking layer EBL11 of the first stack S1 may be covered with the first light emitting layer EML1. In this case, the electron blocking layer of the second stack S2 may be provided in common continuously in multiple subpixels without being patterned for each subpixel. Alternatively, the electron blocking layer may have the same edge as the light emitting layer EML2 or the hole transport auxiliary layer.

As shown in FIG. 7, in the light emitting display device 3000 according to the third embodiment of the present disclosure, a dummy pattern DAN of the same material as the first electrode AND is further provided in a part of the non-light emitting portion, to facilitate release of holes to the light emitting layer EML1 directly contacting the edge EBLE11 of the first electron blocking layer EBL11 when switching from the on-state to the off-state. When switching from the on-state to the off-state, holes may be easily released directly from the light emitting layer EML1 in the region where the light emitting layer EML1 contacts the first common layer CML1 with a small HOMO energy level difference ΔE1 therebetween to the hole transport layer HTL1 of the first common layer CML1, so that hole release to the overlapping dummy pattern 152 is easy.

As such, in the third embodiment, a region of the dummy pattern DAN in which the electron blocking layer EBL11 has a large HOMO energy level difference from the light emitting layer EML1 of the first stack S1 is omitted, so that direct contact between the first color light emitting layer and the first common layer or the second color light emitting layer having a small HOMO energy level difference is possible on the dummy pattern, so that holes are easily released from the first color light emitting layer to the dummy pattern when switched to the off state.

DANR, shown in the drawing, means an area where the dummy pattern DAN is provided.

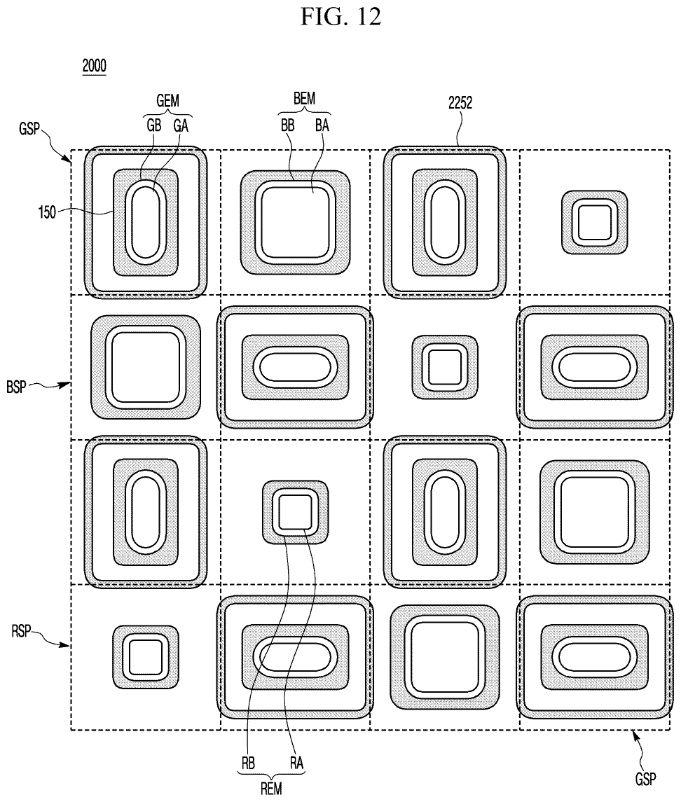

FIG. 12 is a plan view illustrating a light emitting display device according to an embodiment of the present disclosure.

As shown in FIG. 12, the light emitting display device 2000 according to one embodiment of the present disclosure may have a dummy pattern 2252 having a closed loop shape around the first subpixel GSP.

The light emitting display device 2000 according to one embodiment of the present disclosure is provided with a region in which the electron-blocking layer, which has a high tendency to trap holes on the dummy pattern 2252 in a vertical structure, is omitted by disposing a component that may be used as a charge discharging source of the dummy pattern 2252 around the first subpixel having an electron-blocking layer having a relatively low HOMO energy level.

In the area where the electron blocking layer is omitted in the intermediate layer of the dummy pattern 2252, direct contact between the first color light emitting layer GEML and the first common layer CML1 is provided, so that holes are released from the first color light emitting layer GEML in the absence of a large energy barrier in the interlayer arrangement between the dummy pattern 2252 without being trapped by the electron blocking layer, to prevent visibility defects such as screen dragging.

In the light emitting display device according to one embodiment of the present disclosure, the dummy pattern 2252 may have a closed ring shape surrounding the first subpixel.

In this case, the edge of the first electron blocking layer and the edge of the first color light emitting layer may be provided such that they overlap the dummy pattern 2252 of the closed ring shape to facilitate the design of the light emitting display device.

Meanwhile, the cross-sectional configuration described in FIGS. 3 to 11 may be selectively applied to the planar configuration of the light emitting display device of FIG. 12, to provide the same effect.

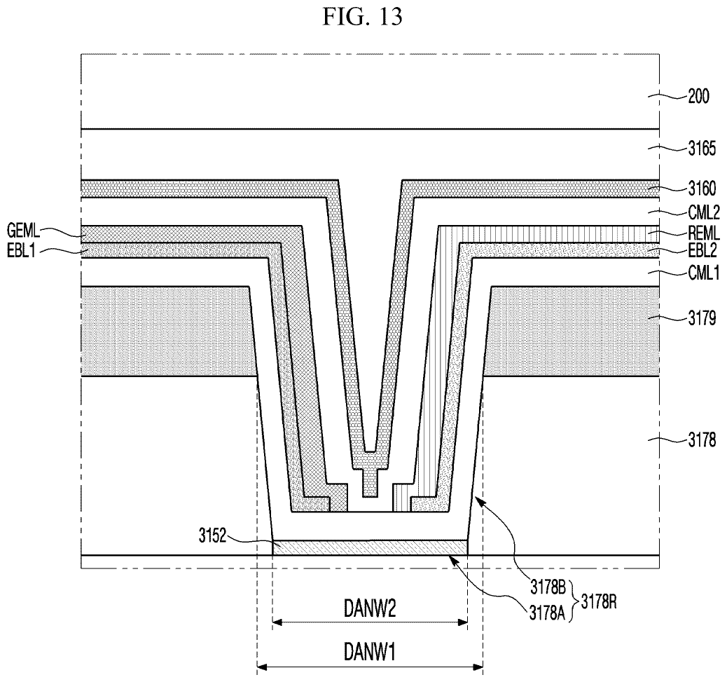

FIG. 13 is a cross-sectional view illustrating a dummy pattern region according to another embodiment of a light emitting display device according to the present disclosure.

As shown in FIG. 13, the light emitting display device according to another embodiment of the present disclosure includes, in a first insulating film 3178, a recess portion 3178R including a bottom surface 3178A and a side surface 3178B surrounding the bottom surface 3178A, and a dummy pattern 3152 provided on the bottom surface 3178A of the recess portion 3178R. Referring to FIG. 13, the bottom surface 3178A overlapping the dummy pattern 3152 may have the same depth as the bottom surface 178A for forming the first electrode in the light emitting portion described in FIG. 3. A fourth insulating film 3179 configured to protect the first electrode may be further disposed on the first insulating film 3178. In the light emitting display device according to the embodiment of FIG. 13, the dummy pattern 3152 may be provided on the bottom surface 3178A within the recessed portion 3178R rather than the upper flat portion of the first insulating film 3178.

In addition, considering the light emitting display device according to another embodiment of the present disclosure with reference to FIG. 13, a first common layer CML1, a first color light emitting layer GEML, a second common layer CML2, and a second electrode 3160 in the area outside the first electron blocking layer EBL1 are sequentially stacked on the dummy pattern 3152 in this order. A capping layer 3165 may be provided on the second electrode 3160. An encapsulation layer 200 may be provided to cover the capping layer 3165.

The first common layer CML1 may include a hole injection layer and a hole transport layer, and the second common layer CML2 may include a hole blocking layer, an electron transport layer, and an electron injection layer. In addition, a hole transport auxiliary layer GHTL and a first electron blocking layer EBL1 may be further included between the hole transport layer and the first color light emitting layer GEML.

The dummy pattern 3152 may be disposed on a flat portion of the first insulating film 3178 and may be exposed by the fourth insulating film 3179.

In the light emitting display device according to another embodiment of the present disclosure according to FIG. 13, a first color light emitting layer GEML may be disposed on a dummy pattern 3152 to surround an edge of a first electron blocking layer EBL1 extended from a first subpixel GSP, and a second color light emitting layer REML may be disposed to surround an edge of a second electron blocking layer EBL2 extended from a second subpixel RSP.

In the embodiment shown in FIG. 13, the dummy pattern 3152 formed of the same material as the first electrode may easily release holes from the first color light emitting layer GEML outside the edge EBL1E of the first electron blocking layer EBL1 to the first common layer CML1 directly contacting the first color light emitting layer GEML when switching from an on-state to an off-state. When switching from the on-state to the off-state, holes may be easily released directly to the first common layer CML1 in the region where the first color light emitting layer GEML comes into contact with the first common layer CML1 having a small HOMO energy level difference, and thus holes may be easily released to the overlapping dummy pattern 3152.

In the embodiment shown in FIG. 13, the dummy pattern 3152 is formed within the recess portion 3178R of the first insulating film 3178, so that the width DANW2 of the dummy pattern 3152 functioning as a charge discharging source may be short, unlike the structure of the first and second embodiments, in which the dummy pattern is provided on the upper flat portion of the first insulating film 3178 and the dummy pattern has a width of DANW1 or more. In addition, in the embodiment shown in FIG. 13, the dummy pattern 3152 is disposed on the bottom surface of the first insulating film 3178, so that the path of the intermediate layers CML1, EBL1/EBL2, GEML/REML, CML2 formed on the dummy pattern 3152 may become longer between adjacent subpixels GSP and RSP due to the steep step caused by the thick first insulating film 3178.

Meanwhile, in the embodiment shown in FIG. 13, the path of each common layer CML1, CML2 on the dummy pattern 3152 is lengthened, so that the leakage current caused by the first and second common layers CML1, and CML2 between adjacent subpixels may be reduced.

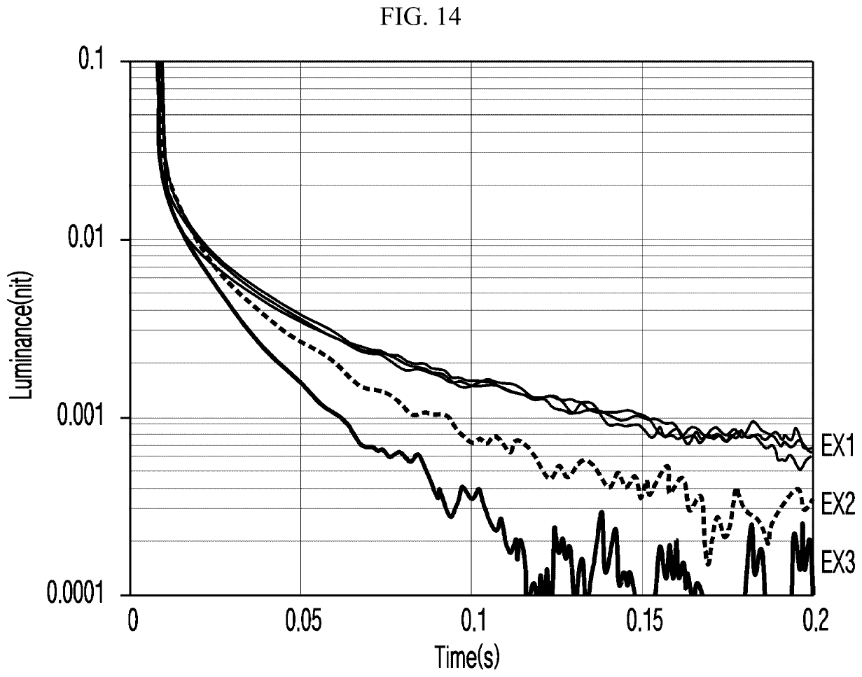

FIG. 14 is a graph showing change in brightness over time in first to third experimental examples when the black screen is driven.

The first experimental example EX1 of FIG. 14 has the same structure as the structure of FIG. 3, except that the dummy pattern is not present and there is no distinction between electron blocking layers of adjacent subpixels. That is, only each color light emitting layer and the hole transport auxiliary layer are separated between adjacent subpixels.

The second experimental example EX2 of FIG. 14 has the same structure as the structure of FIG. 3, except that the dummy pattern is not present and the edge of the first electron blocking layer is surrounded by the first color light emitting layer.

The third experimental example EX3 of FIG. 14 has the same structure as the structure of FIG. 3, except that the dummy pattern is present and the edge of the first electron blocking layer is surrounded by the first color light emitting layer in the area overlapping the dummy pattern.

As can be seen from FIG. 14, when switching to a black screen (when switching from the on state to the off state), the first experimental example does not completely switch to a black state because a certain brightness remains even after a predetermined period of time has elapsed. Comparing the first and second experimental examples, the second experimental example has lower brightness when switching to a black state compared to the first experimental example, using the structure in which the first color light emitting layer surrounds the edge of the first electron blocking layer in the light emitting element. Compared to the first and second experimental examples, the third experimental example may render black after 0.1 seconds when switching to a black screen, so there is almost no delay when switching to a black screen.

That is, it can be seen that the light emitting display device according to the embodiment of the present disclosure solves the problem of poor visibility such as screen dragging even in a structure in which the light emitting portion is extended, using the configuration in which the dummy pattern overlaps the edge of the electron blocking layer and the color light emitting layer for rapid charge discharge from the color light emitting layer when switching to the off state.

The light emitting display device according to the present disclosure has the following effects.

First, the first insulating film on which a first electrode (pixel electrode) is placed is provided such that a recess portion is provided for each subpixel and the first electrode is provided on the bottom surface and the side surface in the recess portion of the first insulating film, so that the light emitting portion using a front surface and the side surface in the recess portion as a light emitting area may be expanded.

Second, a dummy pattern comprising the same material as the first electrode is provided on the flat portion between the recess portions of the first insulating film, so that charges accumulated in the organic layer overlapping the dummy pattern may be released to the dummy pattern in the off state and screen dragging in the off state may be prevented.

Third, the area of the first electrode disposed on the side surface of the recess portion of the first insulating film is used as a light emitting portion and the expanded light emitting portion provides advantages of providing low-power operation and improved efficiency. Accordingly, advantageously, it is possible to operate at a low power from the perspective of high efficiency and high brightness, and to realize a layer structure included in the light emitting element without adding separate materials, and thus to obtain sustainability and ESG (environmental/social/governance) effects.

A light emitting display device according to one embodiment of the present disclosure may comprise a first insulating film having recess portions and a flat portion between adjacent recess portions at first and second subpixels adjacent to each other, a first electrode in a recess portion of each of the first and second subpixels, a dummy pattern on the flat portion of the first insulating film and spaced apart from the first electrode, a first electron blocking layer at the first subpixel and a second electron blocking layer at the second subpixel, the first electron blocking layer and the second electron blocking layer having an edge on the dummy pattern and being spaced apart from each other, a first color light emitting layer at the first subpixel, the first color light emitting layer covering the edge of the first electron blocking layer, a second color light emitting layer on the second electron blocking layer and a second electrode on the first and second color light emitting layers.

In a light emitting display device according to one embodiment of the present disclosure, the second color light emitting layer may cover the edge of the second electron blocking layer.

In a light emitting display device according to one embodiment of the present disclosure, the second color light emitting layer may not overlap the first electron blocking layer.

In a light emitting display device according to one embodiment of the present disclosure, each of the first color light emitting layer and the second color light emitting layer may overlap the dummy pattern.

In a light emitting display device according to one embodiment of the present disclosure, a highest occupied molecular orbital (HOMO) energy level of the first electron blocking layer may be lower than an HOMO energy level of the first color light emitting layer.

A light emitting display device according to one embodiment of the present disclosure may further comprise a first common layer between the first electrode and the first and second electron-blocking layers and a second common layer between the first and second color light emitting layers and the second electrode. The first electron-blocking layer or the second electron-blocking layer may have a lower HOMO energy level than an HOMO energy level of each of the first common layer, the first color light emitting layer and the second color light emitting layer.

A light emitting display device according to one embodiment of the present disclosure may further comprise a first transport auxiliary layer overlapping the first color light emitting layer and disposed between the first electrode and the first electron blocking layer and a second transport auxiliary layer overlapping the second color light emitting layer and disposed between the first electrode and the second electron blocking layer.

In a light emitting display device according to one embodiment of the present disclosure, an HOMO energy level difference between the first color light emitting layer and the first transport auxiliary layer at a non-overlapping region with the first and second electron blocking layers on the dummy pattern may be smaller than an HOMO energy level difference between the first color light emitting layer and the first electron blocking layer on the first electrode of the first subpixel.

In a light emitting display device according to one embodiment of the present disclosure, the first color light emitting layer may be disposed in two or more layers at the first subpixel. The two or more layers may be overlap each other with a charge generation layer therebetween.

In a light emitting display device according to one embodiment of the present disclosure, the dummy pattern may comprise a same material as the first electrode.

In a light emitting display device according to one embodiment of the present disclosure, the first electrode may be provided along a bottom surface of the recess portion and a side surface surrounding the bottom surface of the recess portion at each of the first subpixel and the second subpixel.

In a light emitting display device according to one embodiment of the present disclosure, the first electrode may further comprise an extension portion extending from a side surface of the recess portion to an upper surface of the first insulating film, and the extension portion of the first electrode and the dummy pattern may have a same vertical phase.

A light emitting display device according to one embodiment of the present disclosure may further comprise an encapsulation layer on the second electrode.

A light emitting display device according to one embodiment of the present disclosure may further comprise a touch unit on the second electrode, the touch unit comprising a first touch electrode for transmitting a touch control signal and a second touch electrode for receiving touch information. At least one of the first touch electrode and the second touch electrode may overlap the dummy pattern.

In a light emitting display device according to one embodiment of the present disclosure, the dummy pattern may be in a floating state.

In a light emitting display device according to one embodiment of the present disclosure, the dummy pattern may have a different potential from a potential of the first electrode at the first subpixel in an off state of the first subpixel.

In a light emitting display device according to one embodiment of the present disclosure, the dummy pattern may be provided along a longitudinal direction of a light emitting portion of the first subpixel.

In a light emitting display device according to one embodiment of the present disclosure, the dummy pattern may be spaced apart from an edge of a light emitting portion of the first subpixel and may be provided as a plurality of islands spaced apart from the light emitting portion of the first subpixel.

In a light emitting display device according to one embodiment of the present disclosure, the dummy pattern may have a closed loop surrounding the first subpixel.

In a light emitting display device according to one embodiment of the present disclosure, the first color light emitting layer may emit light with a wavelength of 500 nm to 590 nm, and the second color light emitting layer may emit light with a longer wavelength than the wavelength of the first color light emitting layer.

In a light emitting display device according to one embodiment of the present disclosure, the dummy pattern may be a charge emission source for discharging a charge from the first electron blocking layer on the dummy pattern.

It will be apparent to those skilled in the art that various modifications and variations may be made in the disclosure without departing from the spirit or scope of the disclosure. Thus, it is intended that the disclosure cover such modifications and variations thereof, provided they fall within the scope of the appended claims and their equivalents.

What is claimed is:

1. A light emitting display device, comprising:
a first insulating film having recess portions and a flat portion between adjacent recess portions at first and second subpixels adjacent to each other;
a first electrode in a recess portion of each of the first and second subpixels;
a dummy pattern on the flat portion of the first insulating film and spaced apart from the first electrode;
a first electron blocking layer at the first subpixel and a second electron blocking layer at the second subpixel, the first electron blocking layer and the second electron blocking layer having an edge on the dummy pattern and being spaced apart from each other;
a first color light emitting layer at the first subpixel, the first color light emitting layer covering the edge of the first electron blocking layer;
a second color light emitting layer on the second electron blocking layer; and
a second electrode on the first and second color light emitting layers.

2. The light emitting display device according to claim 1, wherein the second color light emitting layer covers the edge of the second electron blocking layer.

3. The light emitting display device according to claim 1, wherein the second color light emitting layer does not overlap the first electron blocking layer.

4. The light emitting display device according to claim 1, wherein each of the first color light emitting layer and the second color light emitting layer overlaps the dummy pattern.

5. The light emitting display device according to claim 1, wherein a highest occupied molecular orbital (HOMO) energy level of the first electron blocking layer is lower than an HOMO energy level of the first color light emitting layer.

6. The light emitting display device according to claim 1, further comprising:
a first common layer between the first electrode and the first and second electron-blocking layers; and
a second common layer between the first and second color light emitting layers and the second electrode,
wherein the first electron-blocking layer or the second electron-blocking layer has a lower HOMO energy level than an HOMO energy level of each of the first common layer, the first color light emitting layer and the second color light emitting layer.

7. The light emitting display device according to claim 1, further comprising:
a first transport auxiliary layer overlapping the first color light emitting layer and disposed between the first electrode and the first electron blocking layer; and
a second transport auxiliary layer overlapping the second color light emitting layer and disposed between the first electrode and the second electron blocking layer.

8. The light emitting display device according to claim 7, wherein an HOMO energy level difference between the first color light emitting layer and the first transport auxiliary layer at a non-overlapping region with the first and second electron blocking layers on the dummy pattern is smaller than an HOMO energy level difference between the first color light emitting layer and the first electron blocking layer on the first electrode of the first subpixel.

9. The light emitting display device according to claim 1, wherein the first color light emitting layer is disposed in two or more layers at the first subpixel, and the two or more layers overlap each other with a charge generation layer therebetween.

10. The light emitting display device according to claim 1, wherein the dummy pattern comprises a same material as the first electrode.

11. The light emitting display device according to claim 1, wherein the first electrode is provided along a bottom surface of the recess portion and a side surface surrounding the bottom surface of the recess portion at each of the first subpixel and the second subpixel.

12. The light emitting display device according to claim 10, wherein the first electrode further comprises an extension portion extending from a side surface of the recess portion to an upper surface of the first insulating film, and the extension portion of the first electrode and the dummy pattern have a same vertical phase.

13. The light emitting display device according to claim 1, further comprising an encapsulation layer on the second electrode.

14. The light emitting display device according to claim 1, further comprising:
a touch unit on the second electrode, the touch unit comprising:
a first touch electrode for transmitting a touch control signal; and
a second touch electrode for receiving touch information,
wherein at least one of the first touch electrode and the second touch electrode overlaps the dummy pattern.

15. The light emitting display device according to claim 1, wherein the dummy pattern is in a floating state.

16. The light emitting display device according to claim 1, wherein the dummy pattern has a different potential from a potential of the first electrode at the first subpixel in an off state of the first subpixel.

17. The light emitting display device according to claim 1, wherein the dummy pattern is provided along a longitudinal direction of a light emitting portion of the first subpixel.

18. The light emitting display device according to claim 1, wherein the dummy pattern is spaced apart from an edge of a light emitting portion of the first subpixel and is provided as a plurality of islands spaced apart from the light emitting portion of the first subpixel.

19. The light emitting display device according to claim 1, wherein the dummy pattern has a closed loop surrounding the first subpixel.

20. The light emitting display device according to claim 1, wherein the first color light emitting layer is configured to emit light with a wavelength of 500 nm to 590 nm, and
the second color light emitting layer is configured to emit light with a longer wavelength than the wavelength of the first color light emitting layer.

21. The light emitting display device according to claim 1, wherein the dummy pattern is a charge emission source for discharging a charge from the first electron blocking layer on the dummy pattern.
